(19) United States
(12) Patent Application Publication
(10) Pub. No.: US 2023/0236506 A2
(43) Pub. Date: Jul. 27, 2023

(54) RADIATION-SENSITIVE RESIN COMPOSITION AND METHOD OF FORMING RESIST PATTERN

(71) Applicant: JSR CORPORATION, Tokyo (JP)

(72) Inventors: Katsuaki NISHIKORI, Tokyo (JP); Kazuya KIRIYAMA, Tokyo (JP); Takuhiro TANIGUCHI, Tokyo (JP); Ken MARUYAMA, Tokyo (JP)

(73) Assignee: JSR CORPORATION, Tokyo (JP)

(21) Appl. No.: 17/867,739

(22) Filed: Jul. 19, 2022

Related U.S. Application Data
(63) Continuation of application No. PCT/JP2021/000096, filed on Jan. 5, 2021.

(30) Foreign Application Priority Data
Jan. 23, 2020 (JP) 2020-009451

(51) Int. Cl. G03F 7/039; G03F 7/029

(52) U.S. Cl. CPC G03F 7/039; G03F 7/029

(57) ABSTRACT

A radiation-sensitive resin composition includes a polymer and a compound. The compound includes a first structural unit including an aromatic carbon ring to which no less than two hydroxy groups bond, and a second structural unit including an acid-labile group which is dissociable by an action of an acid to give a carboxy group. The compound is represented by formula (1). R¹ represents a monovalent organic group having 1 to 30 carbon atoms; and X⁺ represents a monovalent radiation-sensitive onium cation. A weight average molecular weight of the polymer is no greater than 10,000.

R¹—COO⁻X⁺ (1)

### CROSS-REFERENCE TO RELATED APPLICATIONS

The present application is a continuation application of International Application No. PCT/JP2021/000096, filed Jan. 5, 2021, which claims priority to Japanese Patent Application No. 2020-009451 filed Jan. 23, 2020. The contents of these applications are incorporated herein by reference in their entirety.

### BACKGROUND OF THE INVENTION

### Field of the Invention

The present invention relates to a radiation-sensitive resin composition and a method of forming a resist pattern.

### Discussion of the Background

A radiation-sensitive resin composition for use in microfabrication by lithography generates an acid at a light-exposed region upon irradiation with a radioactive ray, e.g., an electromagnetic wave such as a far ultraviolet ray such as an ArF excimer laser beam (wavelength of 193 nm), a KrF excimer laser beam (wavelength of 248 nm), etc., an extreme ultraviolet ray (EUV) (wavelength of 13.5 nm), or a charged particle ray such as an electron beam. A chemical reaction in which the acid serves as a catalyst causes a difference in rates of dissolution in a developer solution, between light-exposed regions and light-unexposed regions, whereby a resist pattern is formed on a substrate.

The radiation-sensitive resin composition is required to have favorable sensitivity to exposure light such as an extreme ultraviolet ray and an electron beam, as well as superiority in terms of LWR (Line Width Roughness) performance, which indicates line width uniformity, and the like.

To meet these requirements, types, molecular structures, and the like of polymers, acid generating agents, and other components which may be used in radiation-sensitive resin compositions have been investigated, and combinations thereof have been further investigated in detail (see Japanese Unexamined Patent Publication, Publication Nos. 2010-134279, 2014-224984, and 2016-047815).

### SUMMARY OF THE INVENTION

According to an aspect of the present invention, a radiation-sensitive resin composition includes a polymer and a compound. The compound includes a first structural unit including an aromatic carbon ring to which no less than two hydroxy groups bond, and a second structural unit including an acid-labile group which is dissociable by an action of an acid to give a carboxy group. The compound is represented by formula (1). R¹ represents a monovalent organic group having 1 to 30 carbon atoms; and X⁺ represents a monovalent radiation-sensitive onium cation. A weight average molecular weight of the polymer is no greater than 10,000.

R¹—COO⁻X⁺ (1)

According to another aspect of the present invention, a method of forming a resist pattern includes applying a radiation-sensitive resin composition directly or indirectly on a substrate to form a resist film. The resist film is exposed. The resist film exposed is developed. The radiation-sensitive resin composition includes a polymer and a compound. The polymer includes a first structural unit including an aromatic carbon ring to which no less than two hydroxy groups bond, and a second structural unit including an acid-labile group which is dissociable by an action of an acid to give a carboxy group. The compound is represented by formula (1). R¹ represents a monovalent organic group having 1 to 30 carbon atoms; and X⁺ represents a monovalent radiation-sensitive onium cation. A weight average molecular weight of the polymer is no greater than 10,000.

R¹—COO⁻X⁺ (1)

### DESCRIPTION OF EMBODIMENTS

As used herein, the words “a” and “an” and the like carry the meaning of “one or more.” When an amount, concentration, or other value or parameter is given as a range, and/or its description includes a list of upper and lower values, this is to be understood as specifically disclosing all integers and fractions within the given range, and all ranges formed from any pair of any upper and lower values, regardless of whether subranges are separately disclosed. Where a range of numerical values is recited herein, unless otherwise stated, the range is intended to include the endpoints thereof, as well as all integers and fractions within the range. As an example, a stated range of 1-10 fully describes and includes the independent subrange 3.4-7.2 as does the following list of values: 1, 4, 6, 10.

Along with further miniaturization of resist patterns, slight fluctuations in exposure and development conditions have come to exert an increasingly larger effect on configurations and generation of defects of resist patterns. Thus, a radiation-sensitive resin composition with a broad process window (a high process latitude) which enables absorption of such slight fluctuations in process conditions is also required.

According to one embodiment of the invention, a radiation-sensitive resin composition contains: a polymer (hereinafter, may be also referred to as “(A) polymer” or “polymer (A)”) having a first structural unit including an aromatic carbon ring to which no less than two hydroxy groups bond, and a second structural unit including an acid-labile group which is dissociable by an action of an acid to give a carboxy group; and a compound (hereinafter, may be also referred to as “(C) compound” or “compound (C)”) represented by the following formula (1):

R¹—COO⁻X⁺ (1)

wherein, in the formula (1), R¹ represents a monovalent organic group having 1 to 30 carbon atoms; and X⁺ represents a monovalent radiation-sensitive onium cation,

wherein a weight average molecular weight of the polymer (A) is no greater than 10,000.

According to an other embodiment of the invention, a method of forming a resist pattern includes: applying the radiation-sensitive resin composition according to the one embodiment of the invention directly or indirectly on a substrate; exposing a resist film formed by the applying; and developing the resist film exposed.

The radiation-sensitive resin composition and the method of forming a resist pattern according to the embodiments of the present invention enable formation of a resist pattern with favorable sensitivity to exposure light, superiority in terms of LWR performance, and a broad process window. Therefore, these can be suitably used in manufacturing processes of semiconductor devices and the like, in which further progress of miniaturization is expected in the future.

Hereinafter, the radiation-sensitive resin composition and the method of forming a resist pattern according to the embodiments of the present invention will be explained in detail.

### Radiation-Sensitive Resin Composition

The radiation-sensitive resin composition according to the one embodiment of the present invention contains the polymer (A) and the compound (C). The radiation-sensitive resin composition typically contains an organic solvent (hereinafter, may be also referred to as “(D) organic solvent” or “organic solvent (D)”). The radiation-sensitive resin composition may contain, as a favorable component, a radiation-sensitive acid generator (hereinafter, may be also referred to as “(B) acid generator” or “acid generator (B)”). The radiation-sensitive resin composition may also contain, within a range not leading to impairment of the effects of the present invention, other optional component(s).

Due to the polymer (A) and the compound (C) being contained, the radiation-sensitive resin composition enables a resist pattern to be formed with favorable sensitivity to exposure light, superiority in terms of LWR performance, and a broad process window. Although not necessarily clarified and without wishing to be bound by any theory, the reason for achieving the aforementioned effects by the radiation-sensitive resin composition due to involving such a constitution may be presumed, for example, as in the following. When the polymer (A) contained in the radiation-sensitive resin composition has the first structural unit including the aromatic carbon ring to which no less than two hydroxy groups bond, it is considered that solubility in a developer solution improves, and as a result, a resist pattern can be formed with favorable sensitivity to exposure light, superiority in terms of LWR performance, and a broad process window. Furthermore, when the weight average molecular weight of the polymer (A) contained in the radiation-sensitive resin composition is no greater than 10,000, it is considered that solubility in a developer solution improves, and as a result, a resist pattern can be formed with favorable sensitivity to exposure light, superiority in terms of LWR performance, and a broad process window. Moreover, due to the polymer (A) and the compound (C) being used in a combination in the radiation-sensitive resin composition, it is presumed that the amount of the acid generated at a light-exposed region increases, and as a result, the radiation-sensitive resin composition enables formation of a resist pattern with favorable sensitivity to exposure light, superiority in terms of LWR performance, and a broad process window.

Each component contained in the radiation-sensitive resin composition will be described below.

### (A) Polymer

The polymer (A) has a structural unit (hereinafter, may be also referred to as “structural unit (I)”) including an aromatic carbon ring to which no less than two hydroxy groups bond, and a structural unit (hereinafter, may be also referred to as “structural unit (I)”) including an acid-labile group which is dissociable by an action of an acid to give a carboxy group. The polymer (A) may also have other structural unit(s) aside from the structural unit (I) and the structural unit (II). The polymer (A) may contain one, or two or more types of each structural unit. The radiation-sensitive resin composition may contain one, or two or more types of polymer (A).

The weight average molecular weight of the polymer (A) is no greater than 10,000. Due to the weight average molecular weight of the polymer (A) being no greater than 10,000, it is considered that solubility in a developer solution improves, and as a result, a resist pattern can be formed with favorable sensitivity to exposure light, superiority in terms of LWR performance, and a broad process window. It is to be noted that, as referred to herein, the “weight average molecular weight” means a polystyrene-equivalent weight average molecular weight (hereinafter, may be also referred to as “Mw”) as determined by gel permeation chromatography (GPC). The lower limit of the Mw of the polymer (A) is preferably 3,000, more preferably 4,000, and still more preferably 4,500. The upper limit of the Mw of the polymer (A) is typically 10,000, preferably 9,800, more preferably 9,600, and still more preferably 9,500. When the Mw of the polymer (A) falls within the above range, the radiation-sensitive resin composition can result in the sensitivity to exposure light, LWR performance, and process window being further improved.

It is to be noted that herein, the Mw and a polystyrene-equivalent number average molecular weight (hereinafter, may be also referred to as “Mn”), as determined by GPC, described later, of the polymer (A) are values measured by GPC under the following conditions.

GPC columns: “G2000 HIXL”×2, “G3000 HXL”×1, and “G4000 HXL”×1, available from Tosoh Corporation

elution solvent: tetrahydrofuran

flow rate: 1.0 mL/min

sample concentration: 1.0% by mass

amount of injected sample: 100 uL

column temperature: 40° C.

detector: differential refractometer

standard substance: mono-dispersed polystyrene

Each structural unit in the polymer (A) will be described in detail below.

Structural Unit (I)

The structural unit (I) is a structural unit including an aromatic carbon ring to which no less than two hydroxy groups bond. When the polymer (A) has the structural unit (I), it is considered that solubility in a developer solution improves, and as a result, a resist pattern can be formed with favorable sensitivity to exposure light, superiority in terms of LWR performance, and a broad process window.

The number of ring atoms of the carbon ring is preferably 6 to 20, more preferably 6 to 14, and still more preferably 6 to 10. It is to be noted that the number of “ring atoms” as referred to means the number of atoms constituting a ring, and in a case of polycyclic ring, the number of “ring atoms” means the number of atoms constituting the polycyclic ring.

Examples of the aromatic carbon ring include a benzene ring, a naphthalene ring, an anthracene ring, a phenanthrene ring, a tetracene ring, a pyrene ring, and the like. Of these, a benzene ring or a naphthalene ring is preferred, and a benzene ring is more preferred.

The number of hydroxy groups bonding to the aromatic carbon ring is typically no less than 2, preferably no less than 2 and no greater than 11, and more preferably 2. When the number of the hydroxy groups falls within this range, the radiation-sensitive resin composition can result in the sensitivity to exposure light, LWR performance, and process window being further improved. Moreover, when the number of the hydroxy groups is 2, two hydroxy groups preferably bond to adjacent carbon atoms in the aromatic carbon ring. In this case, the radiation-sensitive resin composition can result in even further improving the sensitivity to exposure light, LWR performance and process window.

The structural unit (I) is preferably a structural unit (hereinafter, may be also referred to as “structural unit (I-1)”) represented by the following formula (2).

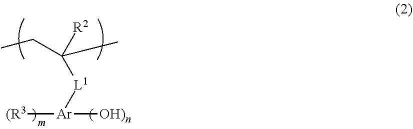

In the above formula (2), R² represents a hydrogen atom, a halogen atom, or a monovalent organic group having 1 to 10 carbon atoms; L¹ represents a single bond, —O—, —COO—, or —CONH—; Ar represents a group obtained by removing (m+n+1) hydrogen atoms of an aromatic ring from an arene having 6 to 20 ring atoms; m is an integer of 0 to 9, wherein in a case in which m is 1, R³ represents a halogen atom or a monovalent organic group having 1 to 10 carbon atoms, and in a case in which m is no less than 2, a plurality of R³s are identical or different from each other and each R³ represents a halogen atom or a monovalent organic group having 1 to 10 carbon atoms, or two or more of the plurality of R³s taken together represent an alicyclic structure having 4 to 20 ring atoms together with the carbon chain to which the two or more of the plurality of R³s bond; and n is an integer of 2 to 11, wherein a sum of m and n is no greater than 11.

Examples of the halogen atom which may be represented by R² or R³ include a fluorine atom, a chlorine atom, a bromine atom, an iodine atom, and the like.

The “organic group” as referred to herein means a group that has at least one carbon atom. The number of “carbon atoms” as referred to herein means the number of carbon atoms constituting a group. The monovalent organic group having 1 to 10 carbon atoms which may be represented by R² or R³ is exemplified by: a monovalent hydrocarbon group having 1 to 10 carbon atoms; a group (α) that contains a divalent hetero atom-containing group between two adjacent carbon atoms of the monovalent hydrocarbon group; a group (β) obtained by substituting with a monovalent hetero atom-containing group, a part or all of hydrogen atoms included in the monovalent hydrocarbon group or the group (α); a group (γ) obtained by combining the monovalent hydrocarbon group, the group (α), or the group (β) with a divalent hetero atom-containing group; and the like.

The “hydrocarbon group” as referred to herein may include a chain hydrocarbon group, an alicyclic hydrocarbon group, and an aromatic hydrocarbon group. The “hydrocarbon group” may be either a saturated hydrocarbon group or an unsaturated hydrocarbon group. The “chain hydrocarbon group” as referred to herein means a hydrocarbon group not containing a cyclic structure but being constituted with only a chain structure, and both a linear hydrocarbon group and a branched hydrocarbon group may be included. The “alicyclic hydrocarbon group” as referred to herein means a hydrocarbon group that contains, as a ring structure, not an aromatic ring structure but an alicyclic structure alone, and may include both a monocyclic alicyclic hydrocarbon group and a polycyclic alicyclic hydrocarbon group. However, it is not necessary for the alicyclic hydrocarbon group to be constituted with only an alicyclic structure; it may contain a chain structure in a part thereof. The “aromatic hydrocarbon group” as referred to herein means a hydrocarbon group that contains an aromatic ring structure as a ring structure. However, it is not necessary for the aromatic hydrocarbon group to be constituted with only an aromatic ring structure; it may contain a chain structure or an alicyclic structure in a part thereof.

The monovalent hydrocarbon group having 1 to 10 carbon atoms is exemplified by a monovalent chain hydrocarbon group having 1 to 10 carbon atoms, a monovalent alicyclic hydrocarbon group having 3 to 10 carbon atoms, a monovalent aromatic hydrocarbon group having 6 to 10 carbon atoms, and the like.

Examples of the monovalent chain hydrocarbon group having 1 to 10 carbon atoms include: alkyl groups such as a methyl group, an ethyl group, an n-propyl group, and an i-propyl group; alkenyl groups such as an ethenyl group, a propenyl group, and a butenyl group; alkynyl groups such as an ethynyl group, a propynyl group, and a butynyl group; and the like.

Examples of the monovalent alicyclic hydrocarbon group having 3 to 10 carbon atoms include: alicyclic saturated hydrocarbon groups such as a cyclopentyl group, a cyclohexyl group, a norbornyl group, and an adamantyl group; alicyclic unsaturated hydrocarbon groups such as a cyclopentenyl group, a cyclohexenyl group, and a norbornenyl group; and the like.

Examples of the monovalent aromatic hydrocarbon group having 6 to 10 carbon atoms include: aryl groups such as a phenyl group, a tolyl group, a xylyl group, and a naphthyl group; aralkyl groups such as a benzyl group and a phenethyl group; and the like.

The hetero atom constituting the monovalent hetero atom-containing group or the divalent hetero atom-containing group is exemplified by an oxygen atom, a nitrogen atom, a sulfur atom, a phosphorus atom, a silicon atom, and a halogen atom. Examples of the halogen atom include a fluorine atom, a chlorine atom, a bromine atom, and an iodine atom.

Examples of the divalent hetero atom-containing group include —O—, —CO—, —S—, —CS—, —NR′—, —SO₂—, a combination of two or more of these, and the like. R′ represents a hydrogen atom or a monovalent hydrocarbon group.

Examples of the arene having 6 to 20 ring atoms that gives Ar include benzene, naphthalene, anthracene, phenanthrene, tetracene, pyrene, and the like.

Examples of the alicyclic structure having 4 to 20 ring atoms represented by the two or more of the plurality of R³s taken together, together with the carbon atom to which the two or more of the plurality of R³s bond include: saturated alicyclic structures such as a cyclopentane structure and a cyclohexane structure; unsaturated alicyclic structures such as a cyclopentene structure and a cyclohexene structure; and the like.

In light of copolymerizability of a monomer that gives the structural unit (I), R² represents preferably a hydrogen atom or a methyl group, and more preferably a hydrogen atom.

L¹ represents preferably a single bond.

The arene having 6 to 20 ring atoms that gives Ar is preferably benzene or naphthalene, and more preferably benzene.

n is preferably 2, in light of enabling the radiation-sensitive resin composition to result in the sensitivity to exposure light, LWR performance, and process window being further improved. In the case in which n is 2, two hydroxy groups preferably bond to adjacent carbon atoms in Ar. In this case, the radiation-sensitive resin composition can result in the sensitivity to exposure light, LWR performance, and process window being even further improved.

m is preferably 0 to 2, more preferably 0 or 1, and still more preferably 0.

The structural unit (I-1) is exemplified by a structural unit (hereinafter, may be also referred to as “structural unit (I-1-1) or (I-1-2)”) represented by the following formula (2-1) or (2-2), and the like.

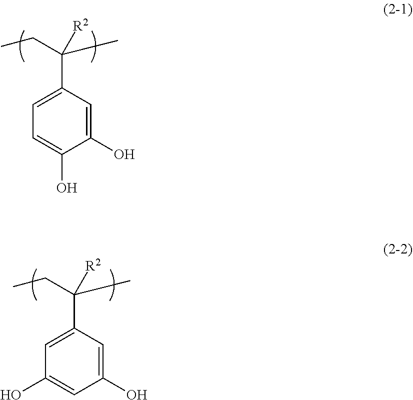

In the above formulae (2-1) and (2-2), R² is as defined in the above formula (2).

The lower limit of a proportion of the structural unit (I) in the polymer (A) contained with respect to total structural units constituting the polymer (A) is preferably 1 mol %, more preferably 5 mol %, and still more preferably 10 mol %. The upper limit of the proportion is preferably 60 mol %, more preferably 50 mol %, and still more preferably 40 mol %. When the proportion of the structural unit (I) falls within the above range, the radiation-sensitive resin composition can result in the sensitivity to exposure light, LWR performance, and process window being further improved.

Structural Unit (II)

The structural unit (II) is a structural unit including an acid-labile group which is dissociable by an action of an acid to give a carboxy group. The “acid-labile group” as referred to means a group that substitutes for a hydrogen atom of a carboxy group, and is dissociable by an action of an acid. When the acid-labile group is dissociated from a carbonyloxy group by an action of an acid, the carboxy group is generated. In the radiation-sensitive resin composition, the acid-labile group in the polymer (A) is dissociated by an action of an acid generated from the acid generator (B) or the like, described later, in the exposing, and thus solubility of the polymer (A) in a developer solution at a light-exposed region is changed, thereby enabling forming the resist pattern.

Examples of the structural unit (II) include a structural unit (hereinafter, may be also referred to as “structural unit (II-1) or (II-2)”) represented by the following formula (3-1) or (3-2), and the like. It is to be noted that in, for example, the following formula (3-1), —C(R⁵)(R⁶)(R⁷) bonding to an oxy oxygen atom derived from the carboxy group corresponds to the acid-labile group.

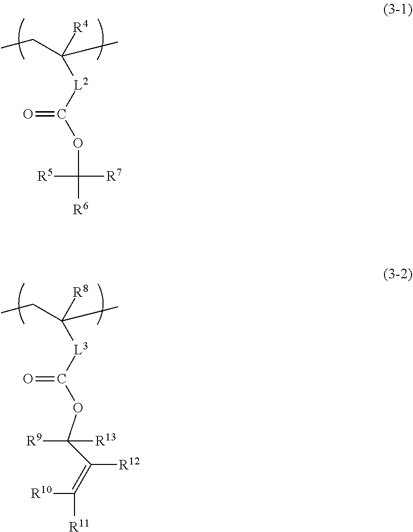

In the above formula (3-1), R⁴ represents a hydrogen atom, a halogen atom, or a monovalent organic group having 1 to 10 carbon atoms; L² represents a single bond or a divalent organic group having 1 to 20 carbon atoms; R⁵ represents a monovalent hydrocarbon group having 1 to 20 carbon atoms; and R⁶ and R⁷ each independently represent a monovalent hydrocarbon group having 1 to 20 carbon atoms, or R⁶ and R⁷ taken together represent an alicyclic structure having 3 to 20 ring atoms together with the carbon atom to which R⁶ and R⁷ bond.

In the above formula (3-2), R⁸ represents a hydrogen atom, a halogen atom, or a monovalent organic group having 1 to 10 carbon atoms; L³ represents a single bond or a divalent organic group having 1 to 20 carbon atoms; R⁹ and R¹⁰ each independently represent a hydrogen atom or a monovalent hydrocarbon group having 1 to 20 carbon atoms, or R⁹ and R¹⁰ taken together represent an unsaturated alicyclic structure having 4 to 20 ring atoms together with the carbon chain to which R⁹ and R¹⁰ bond; R¹¹ represents a hydrogen atom or a monovalent hydrocarbon group having 1 to 20 carbon atoms; and R¹² and R¹³ each independently represent a hydrogen atom or a monovalent hydrocarbon group having 1 to 20 carbon atoms, or R¹² and R¹³ taken together represent an alicyclic structure having 3 to 20 ring atoms together with the carbon chain to which R¹² and R¹³ bond.

Examples of the halogen atom which may be represented by R⁴ or R⁸ include a fluorine atom, a chlorine atom, a bromine atom, and an iodine atom.

Examples of the monovalent organic group having 1 to 10 carbon atoms which may be represented by R⁴ or R⁸ include groups similar to the monovalent organic groups having 1 to 10 carbon atoms exemplified as R² or R³ in the above formula (2), and the like.

Examples of the divalent organic group having 1 to 20 carbon atoms which may be represented by L² or L³ include groups obtained by removing one hydrogen atom from groups similar to the monovalent organic groups exemplified as R² or R³ in the above formula (2), and the like.

Examples of the monovalent hydrocarbon group having 1 to 20 carbon atoms which may be represented by R⁵, R⁶, R⁷, R⁹, R¹⁰, R¹¹, R¹² or R¹³ include groups similar to those exemplified as the monovalent hydrocarbon group, among the monovalent organic groups exemplified as R² or R³ in the above formula (2), and the like.

Examples of the alicyclic structure having 3 to 20 ring atoms which may be represented by R⁶ and R⁷ taken together or R¹² and R¹³ taken together, together with the carbon atom or the carbon chain to which R⁶ and R⁷ or R¹² and R¹³ bond include: monocyclic saturated alicyclic structures such as a cyclopropane structure, a cyclobutane structure, a cyclopentane structure, and a cyclohexane structure; polycyclic saturated alicyclic structures such as a norbornane structure, an adamantane structure, a tricyclodecane structure, and a tetracyclododecane structure; monocyclic unsaturated alicyclic structures such as a cyclopropene structure, a cyclobutene structure, a cyclopentene structure, and a cyclohexene structure; polycyclic unsaturated alicyclic structures such as a norbornene structure, a tricyclodecene structure, and a tetracyclododecene structure; and the like.

Examples of the unsaturated alicyclic structure having 4 to 20 ring atoms which may be represented by R⁹ and R¹⁰ taken together, together with the carbon chain to which R⁹ and R¹⁰ bond include: monocyclic unsaturated alicyclic structures such as a cyclopropene structure, a cyclobutene structure, a cyclopentene structure, and a cyclohexene structure; polycyclic unsaturated alicyclic structures such as a norbornene structure, a tricyclodecene structure, and a tetracyclododecene structure; and the like.

R⁴ or R⁸ represents preferably a hydrogen atom or a methyl group, and more preferably a methyl group.

L² represents preferably a single bond, the divalent aromatic hydrocarbon group, or a group obtained by combining the divalent chain hydrocarbon group and the divalent hetero atom-containing group, and more preferably a single bond. L³ represents preferably a single bond.

R⁵ represents preferably the chain hydrocarbon group or the aromatic hydrocarbon group, and more preferably a methyl group, an ethyl group, an i-propyl group, or a phenyl group.

R⁶ or R⁷ represents preferably the chain hydrocarbon group or the alicyclic hydrocarbon group. Moreover, it is also preferred that R⁶ and R⁷ taken together represent the alicyclic structure having 3 to 20 ring atoms together with the carbon atom to which R⁶ and R⁷ bond. In this case, the alicyclic structure is preferably the monocyclic saturated alicyclic structure or the polycyclic saturated alicyclic structure.

R⁹ or R¹⁰ represents preferably a hydrogen atom or the chain hydrocarbon group. Moreover, it is also preferred that R⁹ and R¹⁰ taken together represent the unsaturated alicyclic structure having 4 to 20 ring atoms together with the carbon chain to which R⁹ and R¹⁰ bond. In this case, the unsaturated alicyclic structure is preferably the monocyclic unsaturated alicyclic structure.

R¹¹ represents preferably a hydrogen atom or the chain hydrocarbon group.

R¹² or R¹³ represents preferably a hydrogen atom. Moreover, it is also preferred that R¹² and R¹³ taken together represent the alicyclic structure having 3 to 20 ring atoms together with the carbon chain to which R¹² and R¹³ bond. In this case, the alicyclic structure is preferably the monocyclic saturated alicyclic structure.

In the above formula (3-2), either R⁹ and R¹⁰ or R¹² and R¹³ preferably constitute a part of the ring structure. Moreover, in the case in which R⁹ and R¹⁰ constitute a part of the ring structure, R¹³ represents preferably a hydrogen atom, or in the case in which R¹² and R¹³ constitute a part of the ring structure, R⁹ represents preferably a hydrogen atom.

The structural unit (II) is preferably the structural unit (II-1), in light of enabling further improving the sensitivity to exposure light and the LWR performance.

Examples of the structural unit (II-1) include structural units (hereinafter, may be also referred to as “structural units (II-1-1) to (II-1-10)”) represented by the following formulae (3-1-1) to (3-1-10), and the like.

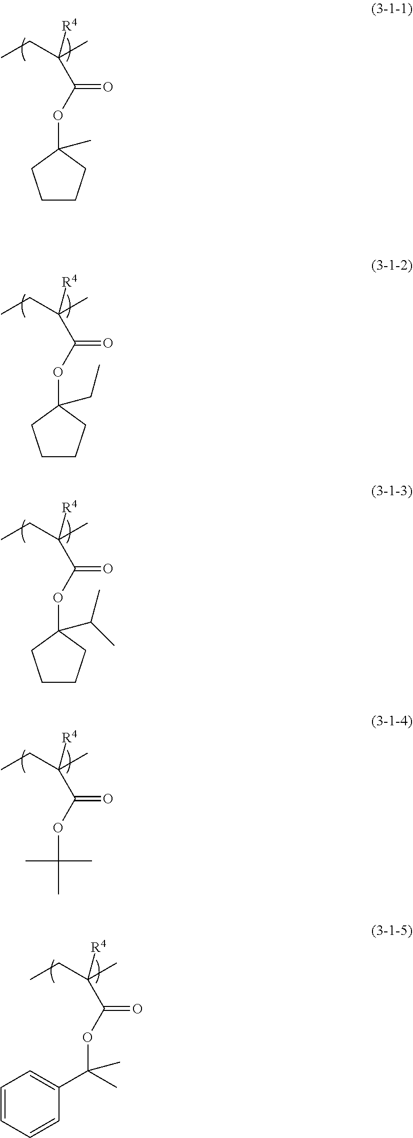

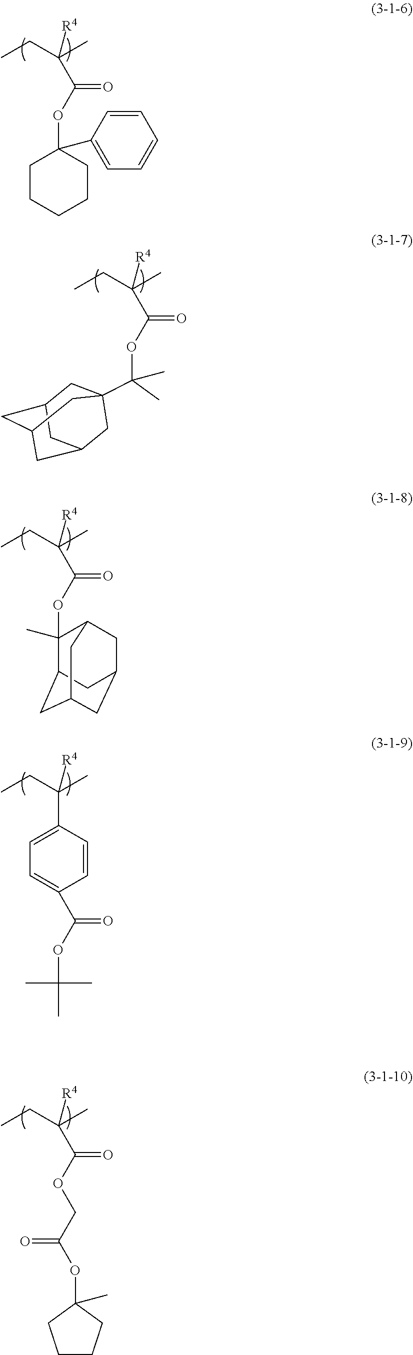

In the above formulae (3-1-1) to (3-1-10), R⁴ is as defined in the above formula (3-1).

The structural unit (II-1) is preferably any one of the structural units (I-1-1) to (II-1-6) or (II-1-8).

Examples of the structural unit (II-2) include structural units (hereinafter, may be also referred to as “structural units (II-2-1) to (II-2-6)”) represented by the following formulae (3-2-1) to (3-2-6), and the like.

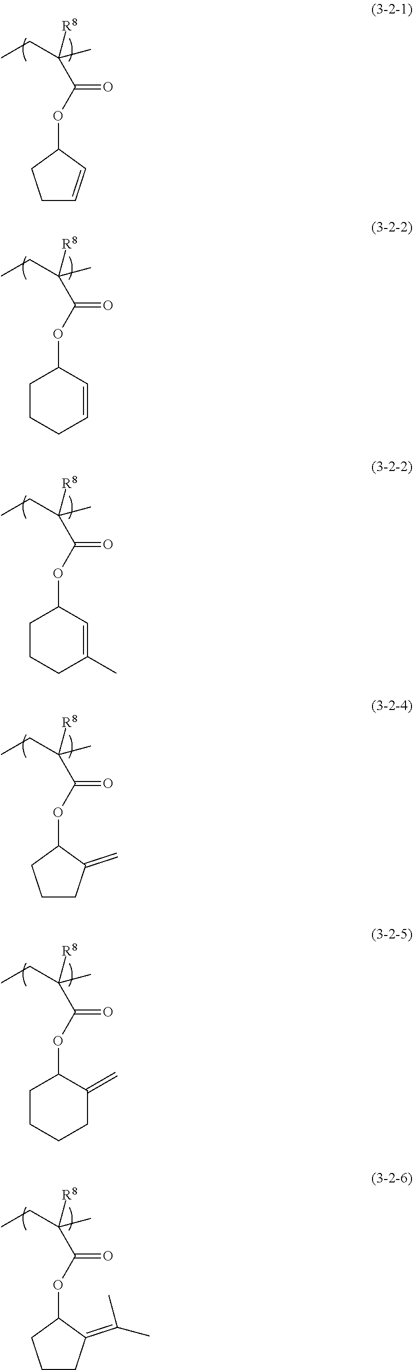

In the above formulae (3-2-1) to (3-2-6), R⁸ is as defined in the above formula (3-2).

The structural unit (II-2) is preferably the structural unit (II-2-3).

The lower limit of a proportion of the structural unit (II) contained in the polymer (A) with respect to total structural units constituting the polymer (A) is preferably 30 mol %, more preferably 40 mol %, and still more preferably 55 mol %. The upper limit of the proportion is preferably 80 mol %, more preferably 70 mol %, and still more preferably 65 mol %.

Other Structural Unit(s)

Other structural unit(s) is/are exemplified by: a structural unit (hereinafter, may be also referred to as “structural unit (III)”) containing an aromatic carbon ring to which one hydroxy group bonds; a structural unit (hereinafter, may be also referred to as “structural unit (IV)”) including an alcoholic hydroxy group; a structural unit (hereinafter, may be also referred to as “structural unit (V)”) including a lactone structure, a cyclic carbonate structure, a sultone structure, or a combination of the same; and the like.

Structural Unit (III)

The structural unit (III) is a structural unit containing an aromatic carbon ring to which one hydroxy group bonds. When the polymer (A) has the structural unit (III), the radiation-sensitive resin composition enables the process window to be further improved.

Examples of the structural unit (III) include structural units represented by the following formulae, and the like.

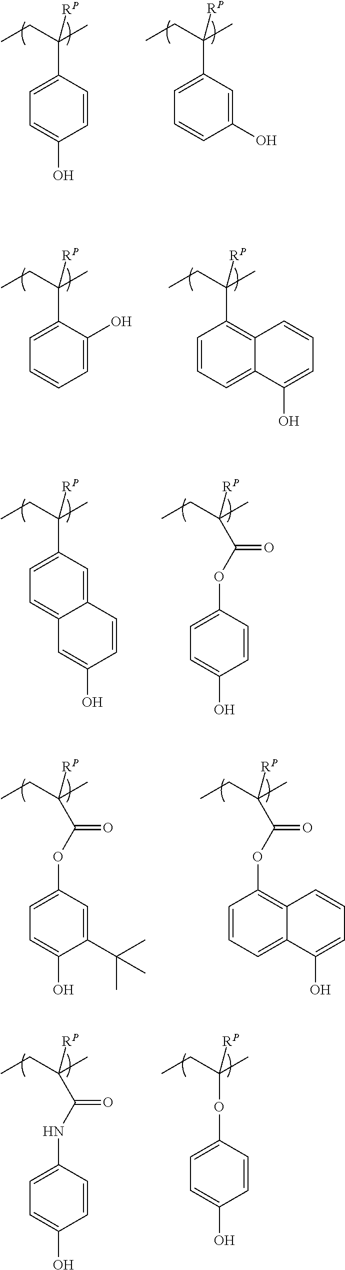

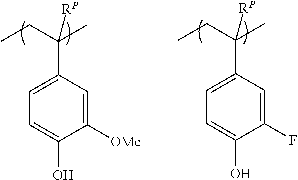

In the above formulae, Re represents a hydrogen atom, a fluorine atom, a methyl group, or a trifluoromethyl group.

In the case in which the polymer (A) has the structural unit (III), the lower limit of a proportion of the structural unit (III) contained is, with respect to total structural units in the polymer (A), preferably 1 mol %, and more preferably 5 mol %. The upper limit of the proportion is preferably 70 mol %, and more preferably 60 mol %.

Structural Unit (IV)

Thee structural unit (IV) is a structural unit including an alcoholic hydroxy group. When the polymer (A) has the structural unit (IV), with regard to the resist pattern formed from the radiation-sensitive resin composition, the LWR performance and the process window can be further improved.

Examples of the structural unit (IV) include structural units represented by the following formulae, and the like.

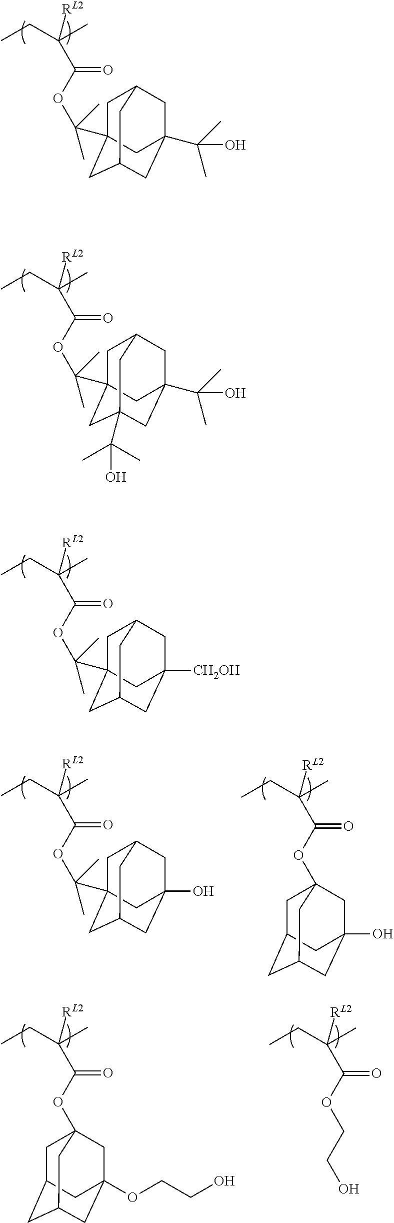

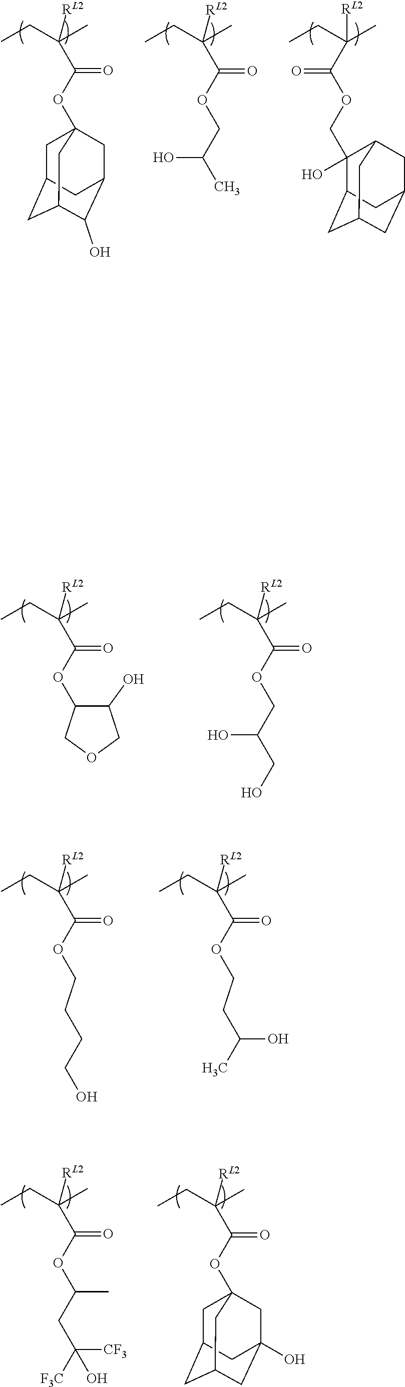

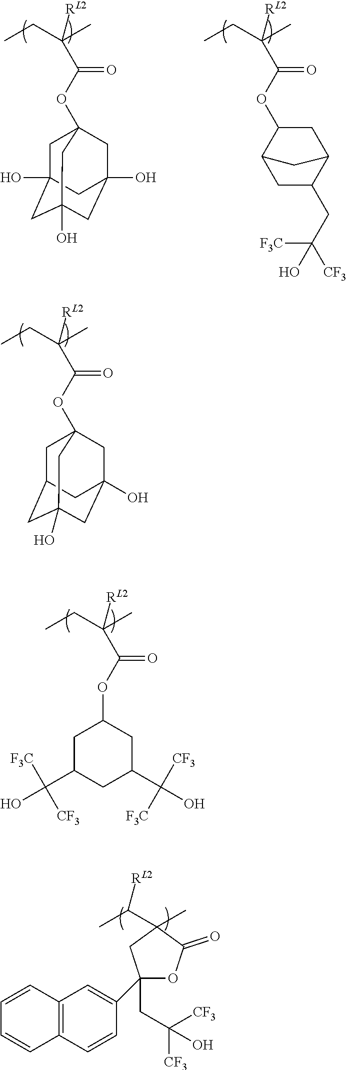

In the above formulae, R^{L2} represents a hydrogen atom, a fluorine atom, a methyl group, or a trifluoromethyl group.

In the case in which the polymer (A) has the structural unit (IV), the lower limit of a proportion of the structural unit (IV) contained is, with respect to total structural units in the polymer (A), preferably 1 mol %, and more preferably 5 mol %. The upper limit of the proportion is preferably 20 mol %, and more preferably 15 mol %.

Structural Unit (V)

The structural unit (V) is a structural unit including a lactone structure, a cyclic carbonate structure, a sultone structure, or a combination of the same. When the polymer (A) has the structural unit (V), with regard to the resist pattern formed from the radiation-sensitive resin composition, further improving the LWR performance and the process window may be enabled.

Examples of the structural unit (V) include structural units represented by the following formulae, and the like.

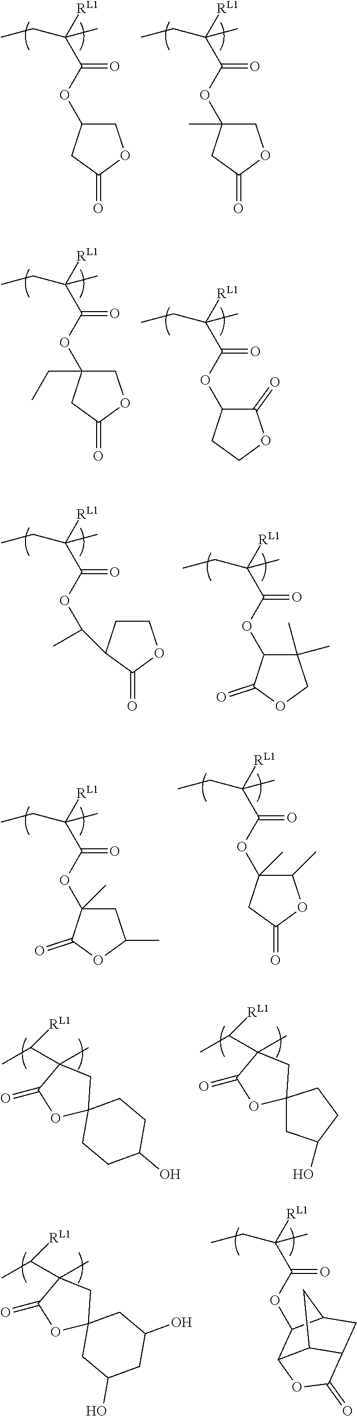

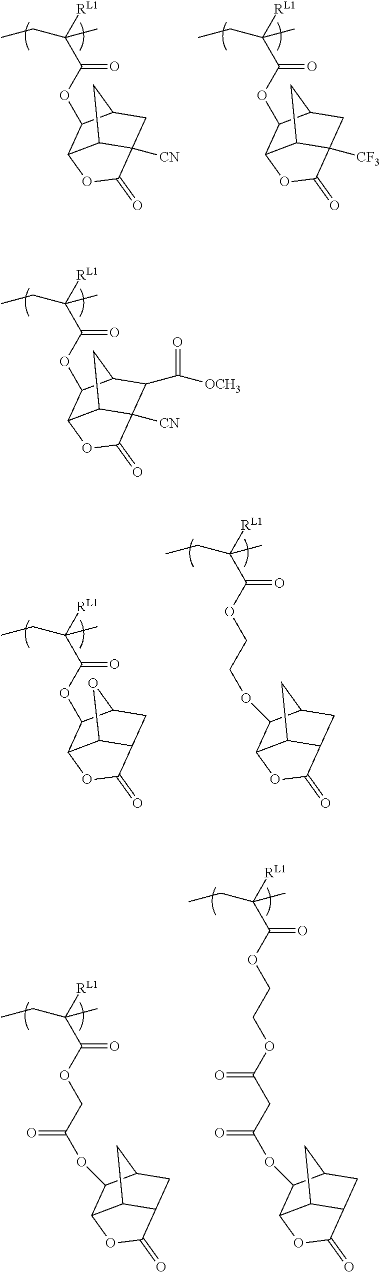

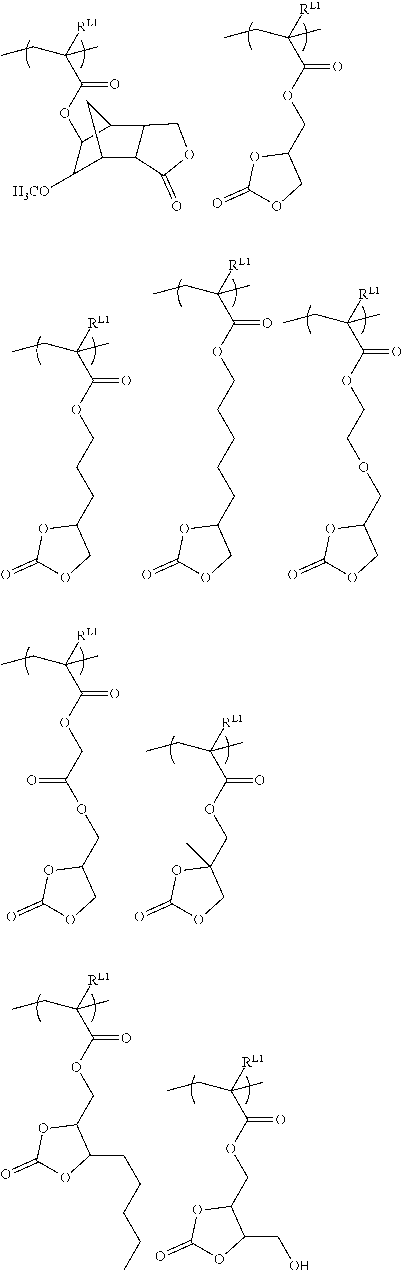

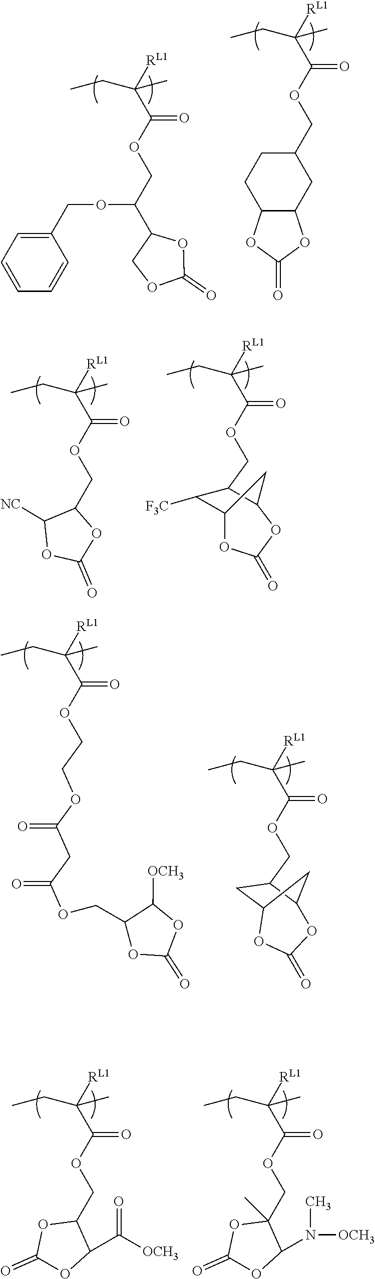

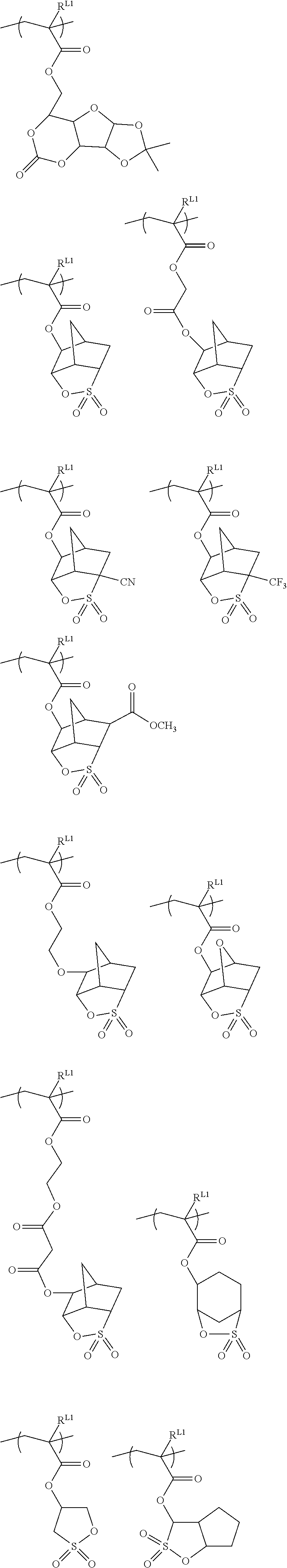

In the above formulae, R^{L1} represents a hydrogen atom, a fluorine atom, a methyl group, or a trifluoromethyl group.

The structural unit (V) is preferably the structural unit including a lactone structure or a cyclic carbonate structure.

In the case in which the polymer (A) has the structural unit (V), the lower limit of a proportion of the structural unit (V) contained is, with respect to total structural units in the polymer (A), preferably 1 mol %, and more preferably 5 mol %. The upper limit of the proportion is preferably 20 mol %, and more preferably 15 mol %.

The upper limit of a ratio (hereinafter, may be also referred to as “Mw/Mn” or “dispersity index”) of the Mw to a polystyrene-equivalent number average molecular weight (Mn) of the polymer (A) as determined by GPC is preferably 2.50, more preferably 2.00, and still more preferably 1.75. The lower limit of the ratio is typically 1.00, preferably 1.10, more preferably 1.20, and still more preferably 1.30. When the Mw/Mn of the polymer (A) falls within the above range, coating characteristics of the radiation-sensitive resin composition can be further improved.

The lower limit of a proportion of the polymer (A) in the radiation-sensitive resin composition with respect to all components other than the organic solvent (D) is preferably 50% by mass, more preferably 60% by mass, still more preferably 70% by mass, and particularly preferably 80% by mass.

The polymer (A) can be synthesized by, for example, polymerizing a monomer that gives each structural unit according to a well-known procedure.

### (B) Acid Generator

The acid generator (B) is a substance which generates an acid by an exposure. Examples of the exposure light include those similar to the ones exemplified as the exposure light in the exposing step of the method of forming a resist pattern, to be described later, and the like. Due to the acid generated by the exposure, the acid-labile group in the structural unit (II) included in the polymer (A) and the like is dissociated to yield a carboxy group, whereby a difference in solubility in the developer solution of the polymer (A) is created between a light-exposed region and a light-unexposed region, and accordingly, forming a resist pattern is enabled.

The lower limit of a temperature at which the acid disassociation of the acid-labile group is permitted is preferably 80° C., more preferably 90° C., and still more preferably 100° C. The upper limit of the temperature is preferably 130° C., more preferably 120° C., and still more preferably 110° C. The lower limit of a time period for the acid to permit disassociation of the acid-labile group is preferably 10 sec, and more preferably 1 min. The upper limit of the time period is preferably 10 min, and more preferably 2 min.

Examples of the acid generated from the acid generator (B) include sulfonic acid, imidic acid, and the like. It is to be noted that the acid generator (B) differs from the compound (C) to be described later.

The form of the acid generator (B) contained in the radiation-sensitive resin composition is exemplified by a form of a low-molecular-weight compound (hereinafter, may be also referred to as “(B) acid generating agent” or “acid generating agent (B)”) described later, a form the acid generator being incorporated as a part of the polymer, and a combination of both these forms. The radiation-sensitive resin composition may contain one, or two or more types of the acid generator (B).

The acid generating agent (B) is exemplified by an onium salt compound, an N-sulfonyloxyimide compound, a sulfonimide compound, a halogen-containing compound, a diazoketone compound, and the like.

Examples of the onium salt compound include sulfonium salts, tetrahydrothiophenium salts, iodonium salts, phosphonium salts, diazonium salts, pyridinium salts, and the like.

Specific examples of the acid generating agent (B) include compounds disclosed in paragraphs [0080] to [0113] of Japanese Unexamined Patent Application, Publication No. 2009-134088, and the like.

The acid generating agent (B) that generates sulfonic acid by the exposure is exemplified by a compound (hereinafter, may be also referred to as “compound (B)”) represented by the following formula (4), and the like.

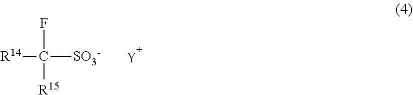

In the above formula (4), R¹⁴ represents a monovalent organic group having 1 to 30 carbon atoms; R¹⁵ represents a hydrogen atom, a fluorine atom, or a monovalent organic group having 1 to 10 carbon atoms; and Y represents a monovalent radiation-sensitive onium cation.

Examples of the monovalent organic group having 1 to 30 carbon atoms represented by R¹⁴ include groups similar to the monovalent organic groups exemplified as R² or R³ in the above formula (2), and the like.

Examples of the monovalent organic group having 1 to 10 carbon atoms which may be represented by R¹⁵ include groups similar to the monovalent organic groups having 1 to 10 carbon atoms exemplified as R² or R³ in the above formula (2), and the like.

The organic group represented by R¹⁴ is preferably a monovalent group containing a ring structure having 5 or more ring atoms. The ring structure having 5 or more ring atoms is exemplified by an alicyclic structure having 5 or more ring atoms, an aliphatic heterocyclic structure having 5 or more ring atoms, an aromatic carbocyclic structure having 5 or more ring atoms, an aromatic heterocyclic structure having 5 or more ring atoms, or a combination of the same, and the like.

Examples of the alicyclic structure having 5 or more ring atoms include:

monocyclic saturated alicyclic structures such as a cyclopentane structure, a cyclohexane structure, a cycloheptane structure, a cyclooctane structure, a cyclononane structure, a cyclodecane structure, and a cyclododecane structure;

monocyclic unsaturated alicyclic structures such as a cyclopentene structure, a cyclohexene structure, a cycloheptene structure, a cyclooctene structure, and a cyclodecene structure;

polycyclic saturated alicyclic structures such as a norbornane structure, an adamantane structure, a tricyclodecane structure, and a tetracyclododecane structure;

polycyclic unsaturated alicyclic structures such as a norbornene structure and a tricyclodecene structure; and the like.

Examples of the aliphatic heterocyclic structure having 5 or more ring atoms include:

lactone structures such as a hexanolactone structure and a norbornanelactone structure;

sultone structures such as a hexanosultone structure and a norbornanesultone structure;

oxygen atom-containing heterocyclic structures such as an oxacycloheptane structure and an oxanorbornane structure;

nitrogen atom-containing heterocyclic structures such as an azacyclohexane structure and a diazabicyclooctane structure;

sulfur atom-containing heterocyclic structures such as a thiacyclohexane structure and a thianorbornane structure; and the like.

Examples of the aromatic carbocyclic structure having 5 or more ring atoms include a benzene structure, a naphthalene structure, a phenanthrene structure, an anthracene structure, and the like.

Examples of the aromatic heterocyclic structure having 5 or more ring atoms include:

oxygen atom-containing heterocyclic structures such as a furan structure, a pyran structure, a benzofuran structure, and a benzopyran structure;

nitrogen atom-containing heterocyclic structures such as a pyridine structure, a pyrimidine structure, and an indole structure; and the like.

The lower limit of a number of ring atoms of the ring structure is preferably 6, more preferably 8, still more preferably 9, and particularly preferably 10. The upper limit of the number of ring atoms is preferably 15, more preferably 14, still more preferably 13, and particularly preferably 12.

R¹⁵ represents preferably a fluorine atom.

The monovalent radiation-sensitive onium cation represented by Y⁺ is exemplified by monovalent cations (hereinafter, may be also referred to as “cations (r-a) to (r-c)”) represented by the following formulae (r-a) to (r-c), and the like.

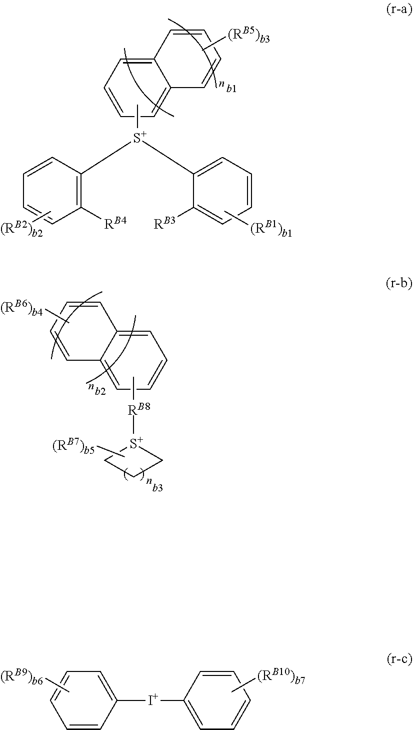

In the above formula (r-a), b1 is an integer of 0 to 4, wherein in a case in which b1 is 1, R^{B1} represents a halogen atom, a hydroxy group, a nitro group, or a monovalent organic group having 1 to 20 carbon atoms, and in a case in which b1 is no less than 2, a plurality of R^{B1}s are identical or different from each other, and each R^{B1} represents a halogen atom, a hydroxy group, a nitro group, or a monovalent organic group having 1 to 20 carbon atoms, or the plurality of R^{B1}s taken together represent a ring structure having 4 to 20 ring atoms together with the carbon chain to which the plurality of R^{B1}s bond; b2 is an integer of 0 to 4, wherein in a case in which b2 is 1, R^{B2} represents a halogen atom, a hydroxy group, a nitro group, or a monovalent organic group having 1 to 20 carbon atoms, and in a case in which b2 is no less than 2, a plurality of R^{B2}s are identical or different from each other, and each R^{B2} represents a halogen atom, a hydroxy group, a nitro group, or a monovalent organic group having 1 to 20 carbon atoms, or the plurality of R^{B2}s taken together represent a ring structure having 4 to 20 ring atoms together with the carbon chain to which the plurality of R^{B2}s bond; R^{B3} and R^{B4} each independently represent a hydrogen atom, a halogen atom, a hydroxy group, a nitro group, or a monovalent organic group having 1 to 20 carbon atoms, or R^{B3} and R^{B4} taken together represent a single bond; b3 is an integer of 0 to 11, wherein in a case in which b3 is 1, R^{B5} represents a halogen atom, a hydroxy group, a nitro group, or a monovalent organic group having 1 to 20 carbon atoms, and in a case in which b3 is no less than 2, a plurality of R^{B5}s are identical or different from each other, and each R^{B}5 represents a halogen atom, a hydroxy group, a nitro group, or a monovalent organic group having 1 to 20 carbon atoms, or the plurality of R^{B5}s taken together represent a ring structure having 4 to 20 ring atoms together with the carbon chain to which the plurality of R^{B5}s bond; and n_{b1} is an integer of 0 to 3.

In the above formula (r-b), b4 is an integer of 0 to 9, wherein in a case in which b4 is 1, R^{B6} represents a halogen atom, a hydroxy group, a nitro group, or a monovalent organic group having 1 to 20 carbon atoms, and in a case in which b4 is no less than 2, a plurality of R^{B6}s are identical or different from each other, and each R^{B6} represents a halogen atom, a hydroxy group, a nitro group, or a monovalent organic group having 1 to 20 carbon atoms, or the plurality of R^{B6}s taken together represent a ring structure having 4 to 20 ring atoms together with the carbon chain to which the plurality of R^{B6}s bond; b5 is an integer of 0 to 10, wherein in a case in which b5 is 1, R^{B7} represents a halogen atom, a hydroxy group, a nitro group, or a monovalent organic group having 1 to 20 carbon atoms, and in a case in which b5 is no less than 2, a plurality of R^{B}Ys are identical or different from each other, and each R^{B7} represents a halogen atom, a hydroxy group, a nitro group, or a monovalent organic group having 1 to 20 carbon atoms, or the plurality of R^{B7}s taken together represent a ring structure having 3 to 20 ring atoms together with the carbon atom or the carbon chain to which the plurality of R^{B7}s bond; n_{b3} is an integer of 0 to 3; R^{B8} represents a single bond or a divalent organic group having 1 to 20 carbon atoms; and n_{b2} is an integer of 0 to 2.

In the above formula (r-c), b6 is an integer of 0 to 5, wherein in a case in which b6 is 1, R^{B9} represents a halogen atom, a hydroxy group, a nitro group, or a monovalent organic group having 1 to 20 carbon atoms, and in a case in which b6 is no less than 2, a plurality of R^{B9}s are identical or different from each other, and each R^{B9} represents a halogen atom, a hydroxy group, a nitro group, or a monovalent organic group having 1 to 20 carbon atoms, or the plurality of R^{B9}s taken together represent a ring structure having 4 to 20 ring atoms together with the carbon chain to which the plurality of R^{B9}s bond; b7 is an integer of 0 to 5, wherein in a case in which b7 is 1, R^{B10} represents a halogen atom, a hydroxy group, a nitro group, or a monovalent organic group having 1 to 20 carbon atoms, and in a case in which b7 is no less than 2, a plurality of R^{B10}s are identical or different from each other, and each R^{B10} represents a halogen atom, a hydroxy group, a nitro group, or a monovalent organic group having 1 to 20 carbon atoms, or the plurality of R^{B10}s taken together represent a ring structure having 4 to 20 ring atoms together with the carbon chain to which the plurality of R^{B10}s bond.

Examples of the monovalent organic group having 1 to 20 carbon atoms which may be represented by R^{B1}, R^{B2}, R^{B3}, R^{B4}, R^{B5}, R^{B6}, R^{B7}, R^{B9} or R^{B10} include groups similar to the groups exemplified as the monovalent organic groups for R² or R³ in the above formula (2), and the like.

Examples of the divalent organic group which may be represented by R^{B8} include groups obtained by removing one hydrogen atom from the groups exemplified as the monovalent organic groups for R² or R³ in the above formula (2), and the like.

It is preferred that R^{B3} and R^{B4} each represent a hydrogen atom, or that R^{B3} and R^{B4} taken together represent a single bond.

It is preferred that b1 and b2 are each 0 to 2. b3 is preferably 0 to 4, more preferably 0 to 2, and still more preferably 0 or 1. n_{b1} is preferably 0 or 1.

In the case in which b1 and b2 are each no less than 1, R^{B1} and R^{B2} each represent preferably a halogen atom or a monovalent organic group having 1 to 20 carbon atoms, more preferably a fluorine atom or a monovalent fluorinated hydrocarbon group having 1 to 20 carbon atoms, and still more preferably a fluorine atom or a trifluoromethyl group. In this case, the sensitivity to exposure light and the LWR performance can be further improved.

In the case in which b3 is no less than 1, R^{B}5 represents preferably a fluorine atom, a cyclohexyl group, or a cyclohexylsulfonyl group.

The monovalent radiation-sensitive onium cation represented by Y⁺ is preferably the cation (r-a).

Examples of the cation (r-a) include cations (hereinafter, may be also referred to as “cations (r-a-1) to (r-a-8)”) represented by the following formulae (r-a-1) to (r-a-8), and the like.

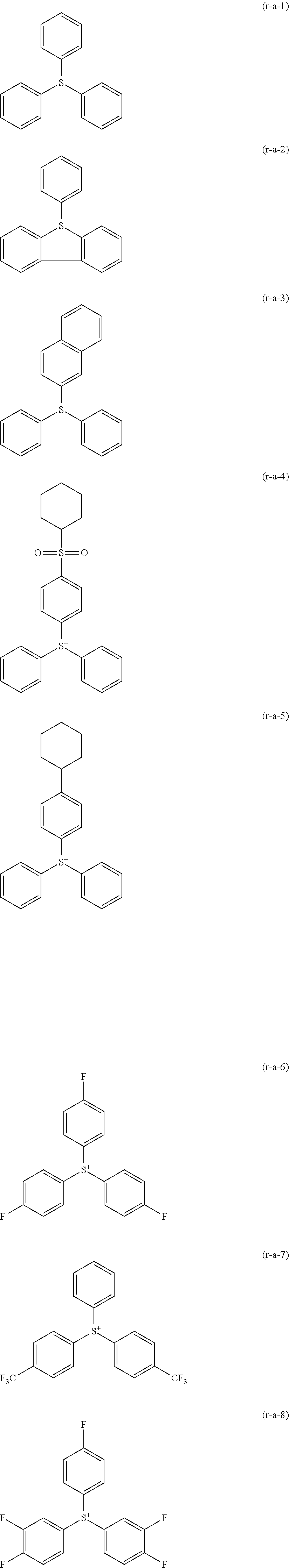

Examples of the compound (B) include compounds (hereinafter, may be also referred to as “compounds (B1) to (B6)”) represented by the following formulae (4-1) to (4-6), and the like.

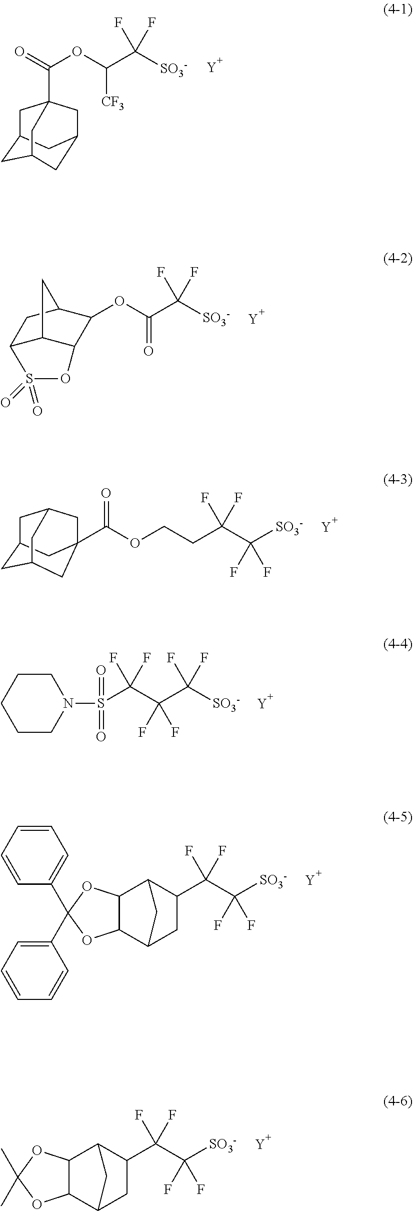

In the above formulae (4-1) to (4-6), Y⁺ is as defined in the above formula (4).

In the case in which the radiation-sensitive resin composition contains the acid generating agent (B), the lower limit of a content of the acid generating agent (B) is, with respect to 100 parts by mass of the polymer (A), preferably 5 parts by mass, more preferably 10 parts by mass, and still more preferably 15 parts by mass. The upper limit of the content is preferably 60 parts by mass, more preferably 55 parts by mass, and still more preferably 50 parts by mass. When the content of the acid generating agent (B) falls within the above range, the radiation-sensitive resin composition can result in the sensitivity to exposure light, LWR performance, and process window being further improved.

### (C) Compound

The compound (C) is a compound represented by the following formula (1). The compound (C) acts as the acid diffusion control agent. The acid diffusion control agent is able to control a diffusion phenomenon in the resist film of the acid generated from the acid generator (B) and the like upon exposure, thereby serving to inhibit unwanted chemical reactions in an unexposed region. Due to the compound (C) being contained, the radiation-sensitive resin composition enables a resist pattern to be formed with favorable sensitivity to exposure light, superiority in terms of LWR performance, and a broad process window.

R¹—COO⁻X⁺ (1)

In the above formula (1), R₁ represents a monovalent organic group having 1 to 30 carbon atoms; and X⁺ represents a monovalent radiation-sensitive onium cation.

Examples of the monovalent organic group having 1 to 30 carbon atoms represented by R¹ include groups similar to the groups exemplified as the monovalent organic groups for R² or R³ in the above formula (2), and the like.

Examples of the monovalent radiation-sensitive onium cation represented by X⁺ include those similar to the monovalent radiation-sensitive onium cations exemplified as Y⁺ in the above formula (4), and the like.

The monovalent radiation-sensitive onium cation represented by X⁺ is preferably the cation (r-a), and more preferably the cation (r-a-1) or the cation (r-a-2).

Examples of the compound (C) include compounds (hereinafter, may be also referred to as “compounds (Cl) to (C4)”) represented by the following formulae (1-1) to (1-4), and the like.

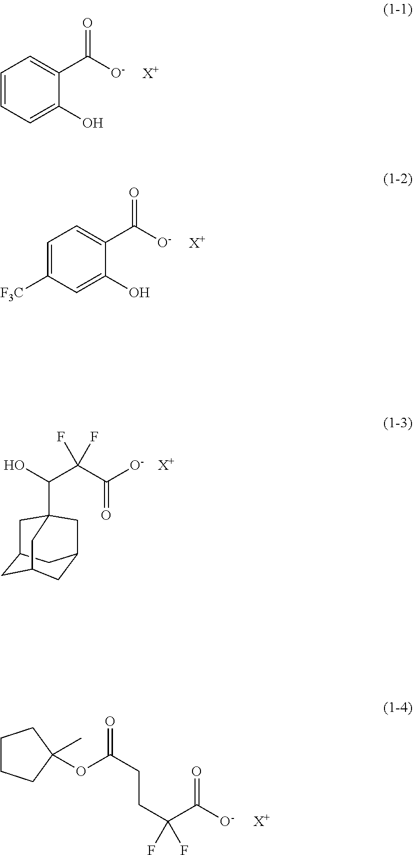

In the above formulae (1-1) to (1-4), X is as defined in the above formula (1).

The lower limit of a proportion of the compound (C) contained in the radiation-sensitive resin composition with respect to 100 mol % of the acid generating agent (B) is preferably 1 mol %, more preferably 5 mol %, and still more preferably 10 mol %. The upper limit of the proportion is preferably 200 mol %, more preferably 100 mol %, and still more preferably 50 mol %. When the proportion of the compound (C) falls within the above range, the radiation-sensitive resin composition can result in the sensitivity to exposure light, LWR performance, and process window being further improved.

### (D) Organic Solvent

The radiation-sensitive resin composition typically contains the organic solvent (D). The organic solvent (D) is not particularly limited as long as it is a solvent capable of dissolving or dispersing at least the polymer (A) and the compound (C), as well as the other optional component(s) which is/are contained as needed.

The organic solvent (D) is exemplified by an alcohol solvent, an ether solvent, a ketone solvent, an amide solvent, an ester solvent, a hydrocarbon solvent, and the like. The radiation-sensitive resin composition may contain one, or two or more types of the organic solvent (D).

Examples of the alcohol solvent include:

aliphatic monohydric alcohol solvents having 1 to 18 carbon atoms such as 4-methyl-2-pentanol and n-hexanol;

alicyclic monohydric alcohol solvents having 3 to 18 carbon atoms such as cyclohexanol;

polyhydric alcohol solvents having 2 to 18 carbon atoms such as 1,2-propylene glycol;

polyhydric alcohol partial ether solvents having 3 to 19 carbon atoms such as propylene glycol-1-monomethyl ether; and the like.

Examples of the ether solvent include:

dialkyl ether solvents such as diethyl ether, dipropyl ether, dibutyl ether, dipentyl ether, diisoamyl ether, dihexyl ether, and diheptyl ether;

cyclic ether solvents such as tetrahydrofuran and tetrahydropyran; aromatic ring-containing ether solvents such as diphenyl ether and anisole; and the like.

Examples of the ketone solvent include:

chain ketone solvents such as acetone, methyl ethyl ketone, methyl n-propyl ketone, methyl n-butyl ketone, diethyl ketone, methyl iso-butyl ketone, 2-heptanone, ethyl n-butyl ketone, methyl n-hexyl ketone, di-iso-butyl ketone, and trimethylnonanone;

cyclic ketone solvents such as cyclopentanone, cyclohexanone, cycloheptanone, cyclooctanone, and methylcyclohexanone;

2,4-pentanedione, acetonylacetone, and acetophenone; and the like.

Examples of the amide solvent include:

cyclic amide solvents such as N,N′-dimethylimidazolidinone and N-methylpyrrolidone;

chain amide solvents such as N-methylformamide, N,N-dimethylformamide, N,N-diethylformamide, acetamide, N-methylacetamide, N,N-dimethylacetamide, and N-methylpropionamide; and the like.

Examples of the ester solvent include:

monocarboxylic acid ester solvents such as n-butyl acetate and ethyl lactate;

lactone solvents such as γ-butyrolactone and valerolactone;

polyhydric alcohol carboxylate solvents such as propylene glycol acetate;

polyhydric alcohol partial ether carboxylate solvents such as propylene glycol monomethyl ether acetate;

polyhydric carboxylic acid diester solvents such as diethyl oxalate;

carbonate solvents such as dimethyl carbonate and diethyl carbonate; and the like.

Examples of the hydrocarbon solvent include:

aliphatic hydrocarbon solvents having 5 to 12 carbon atoms such as n-pentane and n-hexane;

aromatic hydrocarbon solvents having 6 to 16 carbon atoms such as toluene and xylene; and the like.

The organic solvent (D) is preferably the alcohol solvent and/or the ester solvent, more preferably the polyhydric alcohol partial ether solvent having 3 to 19 carbon atoms and/or the polyhydric alcohol partial ether carboxylate solvent, and still more preferably propylene glycol-1-monomethyl ether and/or propylene glycol monomethyl ether acetate.

In the case of the organic solvent (D) being contained in the radiation-sensitive resin composition, the lower limit of a proportion of the organic solvent (D) with respect to all components contained in the radiation-sensitive resin composition is preferably 50% by mass, more preferably 60% by mass, still more preferably 70% by mass, and particularly preferably 80% by mass. The upper limit of the proportion is preferably 99.9% by mass, more preferably 99.5% by mass, and still more preferably 99.0% by mass.

### Other Optional Component(s)

The other optional component(s) is/are exemplified by a surfactant and the like. The radiation-sensitive resin composition may contain one, or two or more types of the other optional component(s).

### Preparation Procedure of Radiation-Sensitive Resin Composition

The radiation-sensitive resin composition of the one embodiment of the present invention may be prepared, for example, by mixing the polymer (A) and the compound (C), as well as the acid generator (B), the organic solvent (D), the other optional component(s), and the like, which are to be added as needed, in a certain ratio, and preferably filtering a thus resulting mixture through a membrane filter having a pore size of no greater than 0.2 μm.

### Method of Forming Resist Pattern

The method of forming a resist pattern according to the other embodiment of the present invention includes: a step of applying the radiation-sensitive resin composition according to the one embodiment of the invention directly or indirectly on a substrate (hereinafter, may be also referred to as “applying step”); a step of exposing a resist film formed by the applying step (hereinafter, may be also referred to as “exposing step”); and a step of developing the resist film exposed (hereinafter, may be also referred to as “developing step”). In the applying step of the method of forming a resist pattern, the radiation-sensitive resin composition described above is used as the radiation-sensitive resin composition.

According to the method of forming a resist pattern, due to using as the radiation-sensitive resin composition in the applying step, the radiation-sensitive resin composition of the one embodiment of the present invention, formation of a resist pattern having favorable sensitivity to exposure light, superiority in terms of the LWR performance, and a broad process window is enabled.

Hereinafter, each step included in the method of forming a resist pattern will be described.

Applying Step

In this step, the radiation-sensitive resin composition is applied directly or indirectly on a substrate, whereby a resist film is formed directly or indirectly on the substrate.

In this step, the radiation-sensitive resin composition described above is used as the radiation-sensitive resin composition.

The substrate is exemplified by a conventionally well-known substrate such as a silicon wafer, a wafer coated with silicon dioxide or aluminum, and the like. In addition, the case of indirectly applying the radiation-sensitive resin composition on the substrate may be, for example, a case of applying the radiation-sensitive resin composition on an antireflective film formed on the substrate, and the like. Such an antireflective film is exemplified by an organic or inorganic antireflective film disclosed in, for example, Japanese Examined Patent Application, Publication No. 16-12452, Japanese Unexamined Patent Application, Publication No. S59-93448, and the like.

An application procedure is exemplified by spin-coating, cast coating, roll-coating, and the like. After the application, soft baking (hereinafter, may be also referred to as “SB”) may be carried out as needed for evaporating the solvent remaining in the coating film. The lower limit of a temperature of the SB is preferably 60° C., and more preferably 80° C. The upper limit of the temperature of the SB is preferably 150° C., and more preferably 140° C. The lower limit of a time period of the SB is preferably 5 sec, and more preferably 10 sec. The upper limit of the time period of the SB is preferably 600 see, and more preferably 300 sec. The lower limit of an average thickness of the resist film formed is preferably 10 nm, and more preferably 20 nm. The upper limit of the average thickness is preferably 1,000 nm, and more preferably 500 nm.

Exposing Step

In this step, the resist film formed by the applying step is exposed. This exposure is carried out by irradiation with an exposure light through a photomask (as the case may be, through a liquid immersion medium such as water). Examples of the exposure light include electromagnetic waves such as visible light rays, ultraviolet rays, far ultraviolet rays, extreme ultraviolet rays (EUV), X-rays, and γ-rays; charged particle rays such as electron beams and α-rays; and the like, which may be selected in accordance with a line width of the intended pattern, and the like. Of these, far ultraviolet rays, EUV, or electron beams are preferred; an ArF excimer laser beam (wavelength: 193 nm), a KrF excimer laser beam (wavelength: 248 nm), EUV (wavelength: 13.5 nm), or an electron beam is more preferred; an ArF excimer laser beam, EUV, or an electron beam is still more preferred; and EUV or an electron beam is particularly preferred.

It is preferred that post exposure baking (hereinafter, may be also referred to as “PEB”) is carried out after the exposure to promote dissociation of the acid-labile group included in the polymer (A) etc., mediated by the acid generated from the acid generator (B), etc., upon the exposure in exposed regions of the resist film. This PEB enables an increase in a difference in solubility of the resist film in a developer solution between the light-exposed regions and light-unexposed regions. The lower limit of a temperature of the PEB is preferably 50° C., more preferably 80° C., and still more preferably 100° C. The upper limit of the temperature of the PEB is preferably 180° C., and more preferably 130° C. The lower limit of a time period of the PEB is preferably 5 see, more preferably 10 sec, and still more preferably 30 sec. The upper limit of the time period of the PEB is preferably 600 sec, more preferably 300 see, and still more preferably 100 sec.

Developing Step

In this step, the resist film exposed is developed. Accordingly, formation of a predetermined resist pattern is enabled. After the development, washing with a rinse agent such as water or an alcohol and then drying is typically performed. The development procedure in the developing step may be carried out by either development with an alkali, or development with an organic solvent.

In the case of the development with an alkali, the developer solution for use in the development is exemplified by alkaline aqueous solutions prepared by dissolving at least one alkaline compound such as sodium hydroxide, potassium hydroxide, sodium carbonate, sodium silicate, sodium metasilicate, aqueous ammonia, ethylamine, n-propylamine, diethylamine, di-n-propylamine, trimethylamine, methyldiethylamine, ethyldimethylamine, triethanolamine, tetramethylammonium hydroxide (hereinafter, may be also referred to as “TMAH”), pyrrole, piperidine, choline, 1,8-diazabicyclo-[5.4.0]-7-undecene, 1,5-diazabicyclo-[4.3.0]-5-nonene, etc., and the like. Of these, an aqueous TMAH solution is preferred, and a 2.38% by mass aqueous TMAH solution is more preferred.

In the case of the development with an organic solvent, the developer solution is exemplified by: an organic solvent such as a hydrocarbon solvent, an ether solvent, an ester solvent, a ketone solvent, and an alcohol solvent; a solution containing the organic solvent; and the like. An exemplary organic solvent includes one, or two or more types of the solvents exemplified as the organic solvent (D) for the radiation-sensitive resin composition, and the like. Of these, the ester solvent or the ketone solvent is preferred. The ester solvent is preferably an acetic acid ester solvent, and more preferably n-butyl acetate. The ketone solvent is preferably a chain ketone, and more preferably 2-heptanone. The lower limit of the content of the organic solvent in the developer solution is preferably 80% by mass, more preferably 90% by mass, still more preferably 95% by mass, and particularly preferably 99% by mass. Components other than the organic solvent in the organic solvent developer solution are exemplified by water, silicone oil, and the like.

Examples of the development procedure include: a dipping procedure in which the substrate is immersed for a given time period in the developer solution charged in a container; a puddle procedure in which the developer solution is placed to form a dome-shaped bead by way of the surface tension on the surface of the substrate for a given time period to conduct a development; a spraying procedure in which the developer solution is sprayed onto the surface of the substrate; a dynamic dispensing procedure in which the developer solution is continuously applied onto the substrate, which is rotated at a constant speed, while scanning with a developer solution-application nozzle at a constant speed; and the like.

The resist pattern to be formed according to the method of forming a resist pattern is exemplified by a line-and-space pattern, a hole pattern, and the like.

### EXAMPLES

Hereinafter, the present invention is explained in detail by way of Examples, but the present invention is not in any way limited to the following Examples. Measuring methods for physical properties are each shown below.

Weight Average Molecular Weight (Mw), Number Average Molecular Weight (Mn), and Dispersity Index (Mw/Mn)

Measurements of the Mw and the Mn of the polymer were carried out by gel permeation chromatography (GPC) using GPC columns available from Tosoh Corporation (“G2000 HXL”×2, “G3000 HXL”×1, and “G4000 HXL”×1) under the following analytical conditions. Furthermore, a dispersity index (Mw/Mn) was calculated according to measurement results of the Mw and the Mn.

elution solvent: tetrahydrofuran

flow rate: 1.0 mL/min

sample concentration: 1.0% by mass

amount of injected sample: 100 μL

column temperature: 40° C.

detector: differential refractometer

standard substance: mono-dispersed polystyrene

### Synthesis of Polymer (A)

Monomers used for synthesizing the polymers in the Examples and Comparative Examples are presented below. It is to be noted that in the following Synthesis Examples, unless otherwise specified particularly, “parts by mass” means a value, provided that the total mass of the monomers used was 100 parts by mass, and “mol %” means a value, provided that the total mol number of the monomers used was 100 mol %.

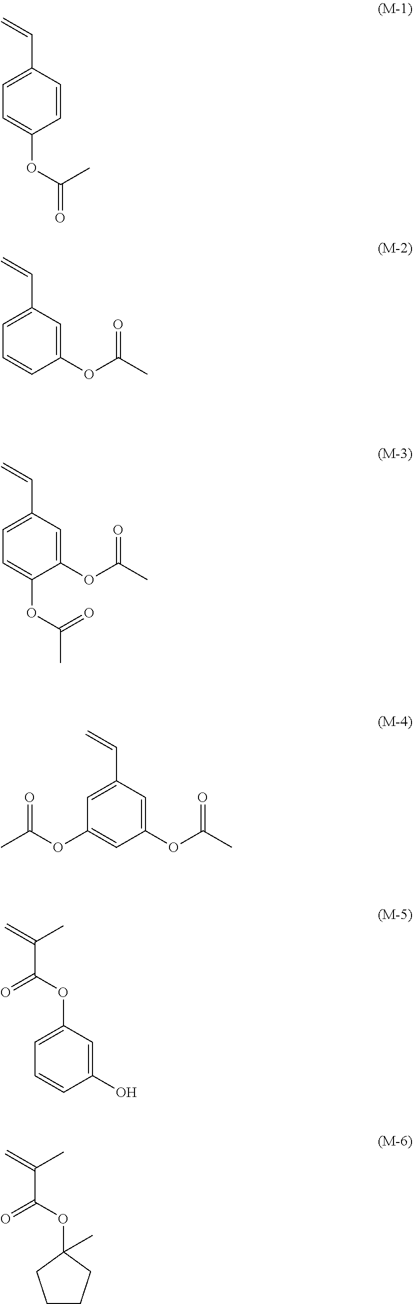

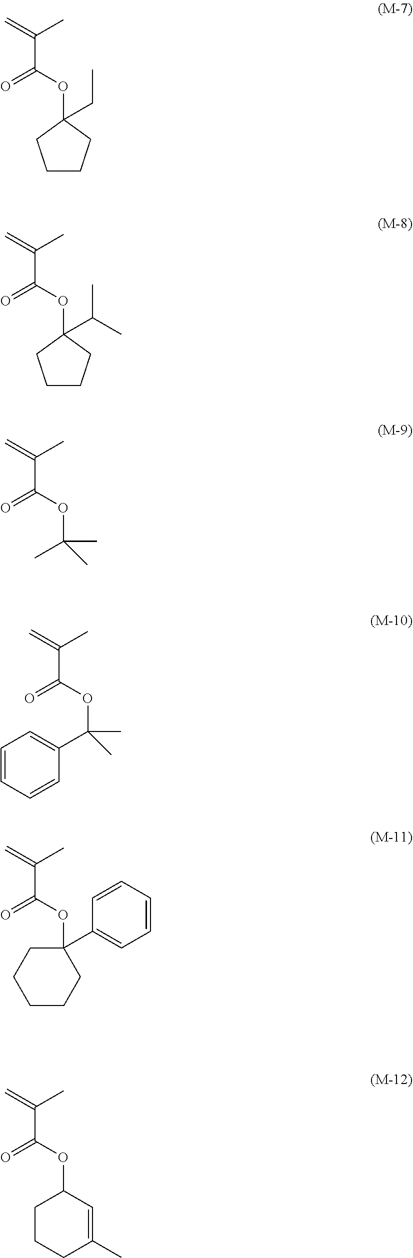

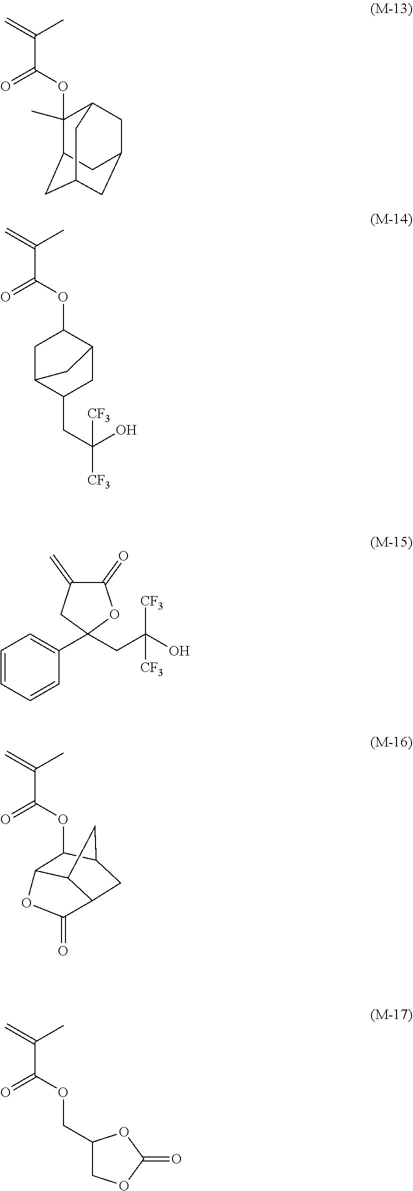

### Synthesis Example 1: Synthesis of Polymer (A-1)

The monomer (M-1), the monomer (M-3), and the monomer (M-6) were dissolved in propylene glycol-1-monomethyl ether (200 parts by mass) such that the molar ratio became 30/10/60. Next, 6 mol % azobisisobutyronitrile (AIBN) was added as an initiator to prepare a monomer solution. Meanwhile, propylene glycol-1-monomethyl ether (100 parts by mass) was charged into an empty reaction vessel and heated to 85° C. with stirring. Next, the monomer solution prepared as described above was added dropwise over 3 hrs, followed by further heating at 85° C. for 3 hrs, whereby the polymerization reaction was performed for 6 hrs in total. After completion of the polymerization reaction, the polymerization solution was cooled to room temperature.

The cooled polymerization solution was charged into hexane (500 parts by mass with respect to the polymerization solution), and a thus precipitated white powder was filtered off. The white powder obtained by the filtration was washed twice with 100 parts by mass of hexane with respect to the polymerization solution, followed by filtering off and dissolution in propylene glycol-1-monomethyl ether (300 parts by mass). Next, methanol (500 parts by mass), triethylamine (50 parts by mass), and ultra-pure water (10 parts by mass) were added to a resulting solution, and a hydrolysis reaction was performed at 70° C. for 6 hrs with stirring. After completion of the hydrolysis reaction, the remaining solvent was distilled away and a solid thus obtained was dissolved in acetone (100 parts by mass). The solution was added dropwise into 500 parts by mass of water to permit coagulation of the resin, a solid thus obtained was filtered off, and drying at 50° C. for 12 hrs gave a white powdery polymer (A-1). The Mw of the polymer (A-1) obtained was 7,200, and the Mw/Mn was 1.54.

### Synthesis Examples 2 to 26: Synthesis of Polymers (A-2) to (A-23) and (a-1) to (a-3)

Polymers (A-2) to (A-23) and (a-1) to (a-3) were synthesized by a similar operation to that of Synthesis Example 1, except that each monomer of the type and in the blend proportion shown in Table 1 below was used.

The type and the proportion of the monomer that gives each structural unit, and the Mw and the Mw/Mn of each polymer obtained in Synthesis Examples 1 to 26 are shown in Table 1 below. It is to be noted that in Table 1, “-” indicates that the corresponding monomer was not used.

TABLE 1

| | | Monomer that gives | | Monomer that gives | | Monomer that gives | | Monomer that gives | | | |
|---|---|---|---|---|---|---|---|---|---|---|---|
| | | structural unit (I) | | structural unit (II) | | structural unit (III) | | other structural unit | | | |
| | (A) | | proportion | | proportion | | proportion | | proportion | | |
| | Polymer | type | (mol %) | type | (mol %) | type | (mol %) | type | (mol %) | Mw | Mw/Mn |
| Synthesis | A-1 | M-3 | 10 | M-6 | 60 | M-1 | 30 | — | — | 7,200 | 1.54 |
| Example 1 | | | | | | | | | | | |
| Synthesis | A-2 | M-3 | 20 | M-6 | 60 | M-1 | 20 | — | — | 7,100 | 1.65 |
| Example 2 | | | | | | | | | | | |
| Synthesis | A-3 | M-3 | 30 | M-6 | 60 | M-1 | 10 | — | — | 7,400 | 1.59 |
| Example 3 | | | | | | | | | | | |
| Synthesis | A-4 | M-3 | 40 | M-7 | 60 | — | — | — | — | 6,900 | 1.51 |
| Example 4 | | | | | | | | | | | |
| Synthesis | A-5 | M-4 | 10 | M-6 | 60 | M-1 | 30 | — | — | 6,600 | 1.49 |
| Example 5 | | | | | | | | | | | |
| Synthesis | A-6 | M-3 | 20 | M-7 | 60 | M-2 | 20 | — | — | 6,800 | 1.54 |
| Example 6 | | | | | | | | | | | |
| Synthesis | A-7 | M-3 | 20 | M-7 | 60 | M-5 | 20 | — | — | 6,500 | 1.62 |
| Example 7 | | | | | | | | | | | |
| Synthesis | A-8 | M-3 | 10 | M-11 | 60 | M-1 | 30 | — | — | 9,400 | 1.62 |
| Example 8 | | | | | | | | | | | |
| Synthesis | A-9 | M-3 | 10 | M-11 | 60 | M-1 | 30 | — | — | 7,900 | 1.59 |
| Example 9 | | | | | | | | | | | |
| Synthesis | A-10 | M-3 | 10 | M-11 | 60 | M-1 | 30 | — | — | 6,200 | 1.45 |
| Example 10 | | | | | | | | | | | |
| Synthesis | A-11 | M-3 | 10 | M-11 | 60 | M-1 | 30 | — | — | 5,100 | 1.44 |
| Example 11 | | | | | | | | | | | |
| Synthesis | A-12 | M-3 | 10 | M-11 | 50 | M-1 | 40 | — | — | 6,300 | 1.54 |
| Example 12 | | | | | | | | | | | |
| Synthesis | A-13 | M-3 | 10 | M-11 | 40 | M-1 | 50 | — | — | 6,400 | 1.49 |
| Example 13 | | | | | | | | | | | |
| Synthesis | A-14 | M-3 | 10 | M-7 | 60 | M-1 | 30 | — | — | 7,400 | 1.48 |
| Example 14 | | | | | | | | | | | |
| Synthesis | A-15 | M-3 | 10 | M-8 | 60 | M-1 | 30 | — | — | 7,200 | 1.49 |
| Example 15 | | | | | | | | | | | |
| Synthesis | A-16 | M-3 | 10 | M-8 | 45 | M-1 | 30 | — | — | 7,100 | 1.45 |
| Example 16 | | | | M-9 | 15 | | | | | | |
| Synthesis | A-17 | M-3 | 10 | M-10 | 60 | M-1 | 30 | — | — | 7,300 | 1.51 |
| Example 17 | | | | | | | | | | | |
| Synthesis | A-18 | M-3 | 10 | M-12 | 60 | M-1 | 30 | — | — | 7,400 | 1.53 |
| Example 18 | | | | | | | | | | | |
| Synthesis | A-19 | M-3 | 10 | M-12 | 45 | M-1 | 30 | — | — | 6,800 | 1.54 |
| Example 19 | | | | M-13 | 15 | | | | | | |
| Synthesis | A-20 | M-3 | 10 | M-8 | 60 | M-1 | 20 | M-14 | 10 | 6,900 | 1.49 |
| Example 20 | | | | | | | | | | | |
| Synthesis | A-21 | M-3 | 10 | M-8 | 60 | M-1 | 20 | M-15 | 10 | 6,500 | 1.44 |
| Example 21 | | | | | | | | | | | |
| Synthesis | A-22 | M-3 | 10 | M-8 | 60 | M-1 | 20 | M-16 | 10 | 6,600 | 1.51 |
| Example 22 | | | | | | | | | | | |
| Synthesis | A-23 | M-3 | 10 | M-8 | 60 | M-1 | 20 | M-17 | 10 | 6,800 | 1.52 |
| Example 23 | | | | | | | | | | | |
| Synthesis | a-1 | M-3 | 10 | M-6 | 60 | M-1 | 30 | — | — | 15,000 | 1.65 |
| Example 24 | | | | | | | | | | | |
| Synthesis | a-2 | M-3 | 10 | M-6 | 60 | M-1 | 30 | — | — | 11,200 | 1.65 |
| Example 25 | | | | | | | | | | | |
| Synthesis | a-3 | — | — | M-6 | 60 | M-1 | 40 | — | — | 8,000 | 1.55 |
| Example 26 | | | | | | | | | | | |

### Preparation of Radiation-Sensitive Resin Composition

The acid generating agent (B), the compound (C), the acid diffusion control agent other than the compound (C), and the organic solvent (D) used for preparation of the radiation-sensitive resin composition are shown below.

(B) Acid Generating Agent

(B-1) to (B-9): Compounds represented by the following formulae (B-1) to (B-9)

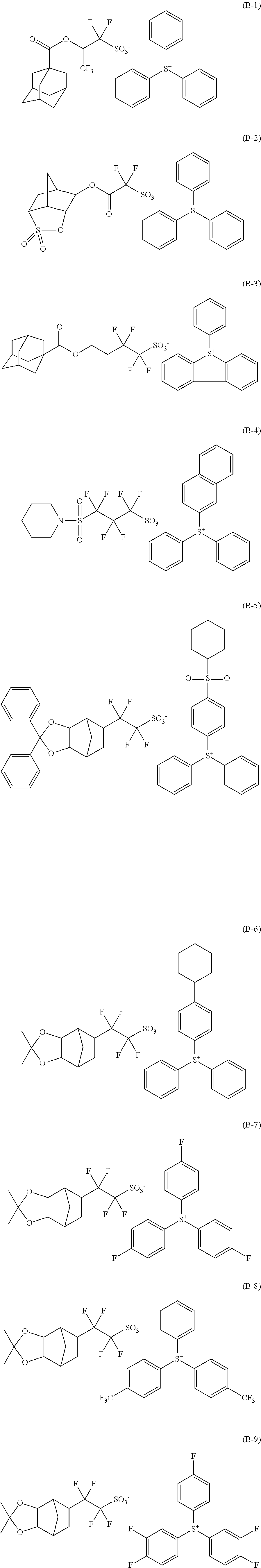

(C) Compound

(C-1) to (C-4): compounds represented by the following formulae (C-1) to (C-4)

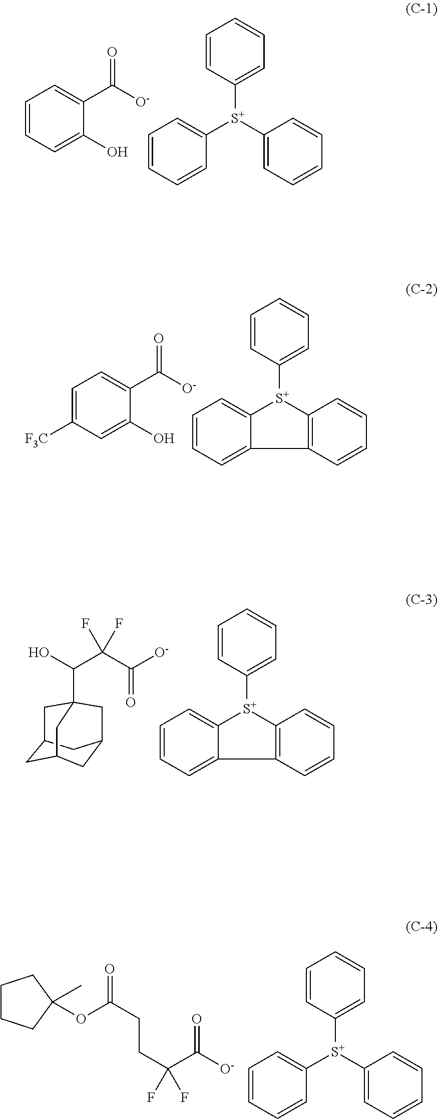

Acid Diffusion Control Agent other than Compound (C)

(c-1) to (c-3): compounds represented by the following formulae (c-1) to (c-3)

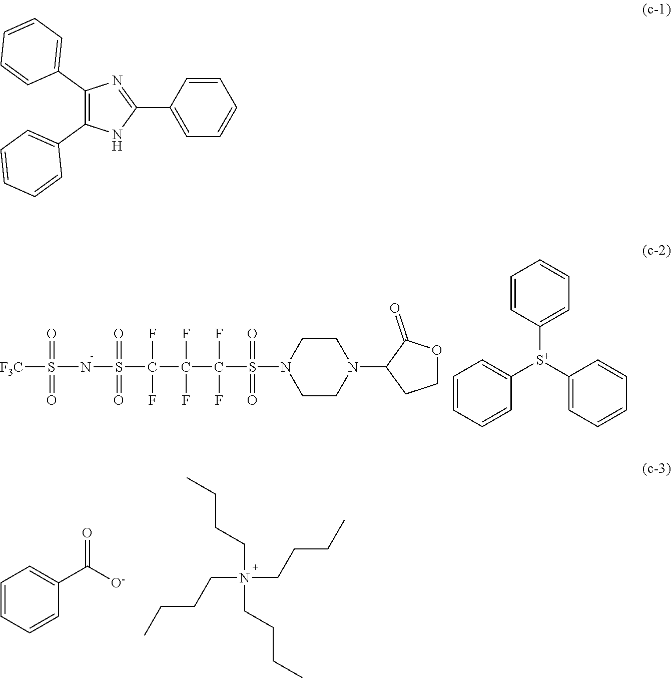

It is to be noted that the cation (tetra n-butylammonium cation) in the compound represented by the above formula (c-3) is not a radiation-sensitive onium cation.

(D) Organic Solvent

(D-1): propylene glycol monomethyl ether acetate

(D-2): propylene glycol-1-monomethyl ether

### Example 1: Preparation of Radiation-Sensitive Resin Composition (R-1)

A radiation-sensitive resin composition (R-1) was prepared by: mixing 100 parts by mass of (A-1) as the polymer (A), 20 parts by mass of (B-1) as the acid generating agent (B), 20 mol % (C-1) with respect to (B-1), as the compound (C), and 4,800 parts by mass of (D-1) and 2,000 parts by mass of (D-2) as the organic solvent (D); and filtering a thus resulting mixture through a membrane filter having a pore size of 0.20 μm.

### Examples 2 to 33 and Comparative Examples 1 to 6: Preparation of Radiation-Sensitive Resin Compositions (R-2) to (R-36) and (CR-1) to (CR-6)

Radiation-sensitive resin compositions (R-2) to (R-36) and (CR-1) to (CR-6) were prepared in a similar manner to Example 1, except that each component of the type and content shown in Table 2 below was used.

TABLE 2

| | Radiation- | | | | | | | | |
|---|---|---|---|---|---|---|---|---|---|
| | sensitive | (A) Polymer | | (B) Acid generating agent | | (C) Compound | | (D) Organic solvent | |
| | resin | | content | | content | | proportion | | content |
| | composition | type | (parts by mass) | type | (parts by mass) | type | (mol %) | type | (parts by mass) |
| Example 1 | R-1 | A-1 | 100 | B-1 | 20 | C-1 | 20 | D-1/D-2 | 4,800/2,000 |
| Example 2 | R-2 | A-2 | 100 | B-1 | 20 | C-1 | 20 | D-1/D-2 | 4,800/2,000 |
| Example 3 | R-3 | A-3 | 100 | B-1 | 20 | C-1 | 20 | D-1/D-2 | 4,800/2,000 |
| Example 4 | R-4 | A-4 | 100 | B-1 | 20 | C-1 | 20 | D-1/D-2 | 4,800/2,000 |
| Example 5 | R-5 | A-5 | 100 | B-1 | 20 | C-1 | 20 | D-1/D-2 | 4,800/2,000 |
| Example 6 | R-6 | A-6 | 100 | B-1 | 20 | C-1 | 20 | D-1/D-2 | 4,800/2,000 |
| Example 7 | R-7 | A-7 | 100 | B-1 | 20 | C-1 | 20 | D-1/D-2 | 4,800/2,000 |
| Example 8 | R-8 | A-8 | 100 | B-1 | 20 | C-1 | 20 | D-1/D-2 | 4,800/2,000 |
| Example 9 | R-9 | A-9 | 100 | B-1 | 20 | C-1 | 20 | D-1/D-2 | 4,800/2,000 |
| Example 10 | R-10 | A-10 | 100 | B-1 | 20 | C-1 | 20 | D-1/D-2 | 4,800/2,000 |
| Example 11 | R-11 | A-11 | 100 | B-1 | 20 | C-1 | 20 | D-1/D-2 | 4,800/2,000 |
| Example 12 | R-12 | A-12 | 100 | B-1 | 20 | C-1 | 20 | D-1/D-2 | 4,800/2,000 |
| Example 13 | R-13 | A-13 | 100 | B-1 | 20 | C-1 | 20 | D-1/D-2 | 4,800/2,000 |
| Example 14 | R-14 | A-14 | 100 | B-1 | 20 | C-1 | 20 | D-1/D-2 | 4,800/2,000 |
| Example 15 | R-15 | A-15 | 100 | B-1 | 20 | C-1 | 20 | D-1/D-2 | 4,800/2,000 |
| Example 16 | R-16 | A-16 | 100 | B-1 | 20 | C-1 | 20 | D-1/D-2 | 4,800/2,000 |
| Example 17 | R-17 | A-17 | 100 | B-1 | 20 | C-1 | 20 | D-1/D-2 | 4,800/2,000 |
| Example 18 | R-18 | A-18 | 100 | B-1 | 20 | C-1 | 20 | D-1/D-2 | 4,800/2,000 |
| Example 19 | R-19 | A-19 | 100 | B-1 | 20 | C-1 | 20 | D-1/D-2 | 4,800/2,000 |
| Example 20 | R-20 | A-20 | 100 | B-1 | 20 | C-1 | 20 | D-1/D-2 | 4,800/2,000 |
| Example 21 | R-21 | A-21 | 100 | B-1 | 20 | C-1 | 20 | D-1/D-2 | 4,800/2,000 |
| Example 22 | R-22 | A-22 | 100 | B-1 | 20 | C-1 | 20 | D-1/D-2 | 4,800/2,000 |
| Example 23 | R-23 | A-23 | 100 | B-1 | 20 | C-1 | 20 | D-1/D-2 | 4,800/2,000 |
| Example 24 | R-24 | A-1 | 100 | B-1 | 30 | C-1 | 20 | D-1/D-2 | 4,800/2,000 |
| Example 25 | R-25 | A-1 | 100 | B-1 | 40 | C-1 | 20 | D-1/D-2 | 4,800/2,000 |
| Example 26 | R-26 | A-1 | 100 | B-2 | 20 | C-1 | 20 | D-1/D-2 | 4,800/2,000 |
| Example 27 | R-27 | A-1 | 100 | B-3 | 20 | C-1 | 20 | D-1/D-2 | 4,800/2,000 |
| Example 28 | R-28 | A-1 | 100 | B-4 | 20 | C-1 | 20 | D-1/D-2 | 4,800/2,000 |
| Example 29 | R-29 | A-1 | 100 | B-5 | 20 | C-1 | 20 | D-1/D-2 | 4,800/2,000 |
| Example 30 | R-30 | A-1 | 100 | B-6 | 20 | C-1 | 20 | D-1/D-2 | 4,800/2,000 |
| Example 31 | R-31 | A-1 | 100 | B-1 | 20 | C-2 | 20 | D-1/D-2 | 4,800/2,000 |
| Example 32 | R-32 | A-1 | 100 | B-1 | 20 | C-3 | 20 | D-1/D-2 | 4,800/2,000 |
| Example 33 | R-33 | A-1 | 100 | B-1 | 20 | C-4 | 20 | D-1/D-2 | 4,800/2,000 |
| Example 34 | R-34 | A-1 | 100 | B-7 | 20 | C-1 | 20 | D-1/D-2 | 4,800/2,000 |
| Example 35 | R-35 | A-1 | 100 | B-8 | 20 | C-1 | 20 | D-1/D-2 | 4,800/2,000 |
| Example 36 | R-36 | A-1 | 100 | B-9 | 20 | C-1 | 20 | D-1/D-2 | 4,800/2,000 |
| Comparative | CR-1 | a-1 | 100 | B-1 | 20 | C-1 | 20 | D-1/D-2 | 4,800/2,000 |
| Example 1 | | | | | | | | | |
| Comparative | CR-2 | a-2 | 100 | B-1 | 20 | C-1 | 20 | D-1/D-2 | 4,800/2,000 |
| Example 2 | | | | | | | | | |
| Comparative | CR-3 | a-3 | 100 | B-1 | 20 | C-1 | 20 | D-1/D-2 | 4,800/2,000 |
| Example 3 | | | | | | | | | |
| Comparative | CR-4 | A-1 | 100 | B-1 | 20 | c-1 | 20 | D-1/D-2 | 4,800/2,000 |
| Example 4 | | | | | | | | | |
| Comparative | CR-5 | A-1 | 100 | B-1 | 20 | c-2 | 20 | D-1/D-2 | 4,800/2,000 |
| Example 5 | | | | | | | | | |
| Comparative | CR-6 | A-1 | 100 | B-1 | 20 | c-3 | 20 | D-1/D-2 | 4,800/2,000 |
| Example 6 | | | | | | | | | |

### Resist Pattern Formation

On a 12-inch silicon wafer surface provided thereon with an underlayer film (“AL412,” available from Brewer Science, Inc.) having an average thickness of 20 nm, the radiation-sensitive resin compositions prepared as described above were each applied using a spin coater (“CLEAN TRACK ACT12,” available from Tokyo Electron Limited), and soft-baking (SB) was conducted at 130° C. for 60 sec. Thereafter, by cooling at 23° C. for 30 see, a resist film having an average thickness of 50 nm was formed. Next, the resist film was irradiated with EUV light using an EUV scanner (“NXE3300”, available from ASML Co.) with NA of 0.33 under an illumination condition of Conventional s=0.89 and with a mask of imecDEFECT32FFR02. The resist film was subjected to post exposure baking (PEB) at 110° C. for 60 sec. Subsequently, a positive-tone resist pattern with 32 nm lines-and-spaces was formed by development at 23° C. for 30 sec by using a 2.38% by mass aqueous TMAH solution

### Evaluations

Each of the resist patterns formed was evaluated on sensitivity, LWR performance, and process window in accordance with the following methods. It is to be noted that a scanning electron microscope (“CG-4100,” available from Hitachi High-Technologies Corporation) was used for line-width measurement of the resist pattern. The results of the evaluations are shown in Table 3 below. It is to be noted that “-” in Table 3 below indicates that in Comparative Example 6, a resist pattern failed to be formed, and it was not possible to conduct each type of evaluation.

### Sensitivity

An exposure dose at which a 32-nm line-and-space pattern was formed in the aforementioned resist pattern formation was defined as an optimum exposure dose, and this optimum exposure dose was adopted as Eop (unit: m/cm²). The sensitivity being more favorable is indicated by the Eop value being smaller. The sensitivity was evaluated to be: “favorable” in a case of the Eop being no greater than 30 mi/cm²; and “unfavorable” in a case of the Eop being greater than 30 mJ/cm².

LWR Performance

The resist patterns formed were observed from above using the scanning electron microscope. Line widths were measured at 50 arbitrary points, and then a 3 Sigma value was determined from distribution of the measurements and was defined as LWR (unit: nm). The value of the LWR being smaller reveals less line rattling, indicating better LWR performance. The LWR performance was evaluated to be: “favorable” in a case of the LWR being no greater than 4.0 nm; and “unfavorable” in a case of the LWR being greater than 4.0 nm.

Process Window

The “process window” as referred to herein means the range of resist dimensions at which a pattern having no bridge defects or collapses can be formed. Using a mask for forming 32 nm lines-and-spaces (1 L/1 S), patterns were formed with low-exposure doses to high-exposure doses. In general, defects in bridge formation and the like can be found in patterns in the case of the low-exposure dose, and defects such as pattern collapses can be found in the case of the high-exposure dose. The difference between the maximum value and the minimum value of resist dimensions at which no such defects were found was considered to be the CD (Critical Dimension) margin (unit: nm). The CD margin being large reveals a broader process window, and is favorable. The CD margin was evaluated to be: “favorable” in a case of being no less than 30 nm; and “unfavorable” in a case of being less than 30 nm.

TABLE 3

| | Radiation-sensitive | Eop | LWR | CD margin |
|---|---|---|---|---|
| | resin composition | (mJ/cm²) | (nm) | (nm) |
| Example 1 | R-1 | 27 | 3.7 | 35 |
| Example 2 | R-2 | 25 | 3.6 | 37 |
| Example 3 | R-3 | 25 | 3.6 | 36 |
| Example 4 | R-4 | 26 | 3.5 | 37 |
| Example 5 | R-5 | 26 | 3.6 | 35 |
| Example 6 | R-6 | 28 | 3.5 | 38 |
| Example 7 | R-7 | 28 | 3.7 | 36 |
| Example 8 | R-8 | 29 | 3.5 | 36 |
| Example 9 | R-9 | 28 | 3.5 | 37 |
| Example 10 | R-10 | 28 | 3.6 | 38 |
| Example 11 | R-11 | 27 | 3.7 | 36 |
| Example 12 | R-12 | 26 | 3.7 | 35 |
| Example 13 | R-13 | 25 | 3.8 | 35 |
| Example 14 | R-14 | 28 | 3.6 | 36 |
| Example 15 | R-15 | 28 | 3.5 | 37 |
| Example 16 | R-16 | 27 | 3.6 | 35 |
| Example 17 | R-17 | 28 | 3.6 | 34 |
| Example 18 | R-18 | 29 | 3.8 | 34 |
| Example 19 | R-19 | 28 | 3.8 | 35 |
| Example 20 | R-20 | 27 | 3.4 | 38 |
| Example 21 | R-21 | 27 | 3.5 | 38 |
| Example 22 | R-22 | 28 | 3.6 | 37 |
| Example 23 | R-23 | 28 | 3.7 | 35 |
| Example 24 | R-24 | 26 | 3.7 | 36 |
| Example 25 | R-25 | 25 | 3.8 | 35 |
| Example 26 | R-26 | 26 | 3.6 | 34 |
| Example 27 | R-27 | 27 | 3.5 | 36 |
| Example 28 | R-28 | 28 | 3.5 | 35 |
| Example 29 | R-29 | 28 | 3.4 | 39 |
| Example 30 | R-30 | 27 | 3.6 | 37 |
| Example 31 | R-31 | 26 | 3.7 | 36 |
| Example 32 | R-32 | 25 | 3.7 | 37 |
| Example 33 | R-33 | 25 | 3.8 | 36 |
| Example 34 | R-34 | 25 | 3.4 | 35 |
| Example 35 | R-35 | 24 | 3.5 | 36 |
| Example 36 | R-36 | 24 | 3.4 | 35 |
| Comparative | CR-1 | 35 | 3.8 | 22 |
| Example 1 | | | | |
| Comparative | CR-2 | 33 | 3.8 | 25 |
| Example 2 | | | | |
| Comparative | CR-3 | 33 | 3.9 | 26 |
| Example 3 | | | | |
| Comparative | CR-4 | 35 | 4.4 | 22 |
| Example 4 | | | | |
| Comparative | CR-5 | 22 | 5.1 | 20 |
| Example 5 | | | | |
| Comparative | CR-6 | — | — | — |
| Example 6 | | | | |

As is clear from the results shown in Table 3, when compared to the radiation-sensitive resin compositions of the Comparative Examples, the radiation-sensitive resin compositions of the Examples were favorable in terms of each of sensitivity, LWR performance, and CD margins.

The radiation-sensitive resin composition and the method of forming a resist pattern of the embodiments of the present invention enable a resist pattern to be formed with favorable sensitivity to exposure light, superiority in terms of LWR performance, and a broad process window. Therefore, these can be suitably used in manufacturing processes of semiconductor devices and the like, in which further progress of miniaturization is expected in the future.

Obviously, numerous modifications and variations of the present invention are possible in light of the above teachings. It is therefore to be understood that within the scope of the appended claims, the invention may be practiced otherwise than as specifically described herein.

What is claimed is:

1. A radiation-sensitive resin composition comprising:
a polymer comprising a first structural unit comprising an aromatic carbon ring to which no less than two hydroxy groups bond, and a second structural unit comprising an acid-labile group which is dissociable by an action of an acid to give a carboxy group; and
a compound represented by formula (1):
R¹—COO⁻X⁺ (1)
wherein, in the formula (1), R¹ represents a monovalent organic group having 1 to 30 carbon atoms; and X⁺ represents a monovalent radiation-sensitive onium cation,
wherein a weight average molecular weight of the polymer is no greater than 10,000.

2. The radiation-sensitive resin composition according to claim 1, wherein the first structural unit is represented by formula (2): 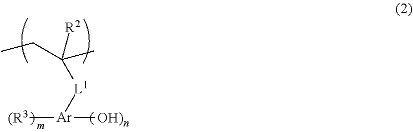
wherein, in the formula (2), R² represents a hydrogen atom, a halogen atom, or a monovalent organic group having 1 to 10 carbon atoms; L¹ represents a single bond, —O—, —COO—, or —CONH—; Ar represents a group obtained by removing (m+n+1) hydrogen atoms of an aromatic ring from an arene having 6 to 20 ring atoms; m is an integer of 0 to 9, wherein in a case in which m is 1, R³ represents a halogen atom or a monovalent organic group having 1 to 10 carbon atoms, and in a case in which m is no less than 2, a plurality of R³s are identical or different from each other and each R³ represents a halogen atom or a monovalent organic group having 1 to 10 carbon atoms, or two or more of the plurality of R³s taken together represent an alicyclic structure having 4 to 20 ring atoms together with the carbon chain to which the two or more of the plurality of R³s bond; and n is an integer of 2 to 11, wherein a sum of m and n is no greater than 11.

3. The radiation-sensitive resin composition according to claim 2, wherein n in the formula (2) is 2.

4. The radiation-sensitive resin composition according to claim 1, wherein the second structural unit is represented by formula (3-1) or (3-2): 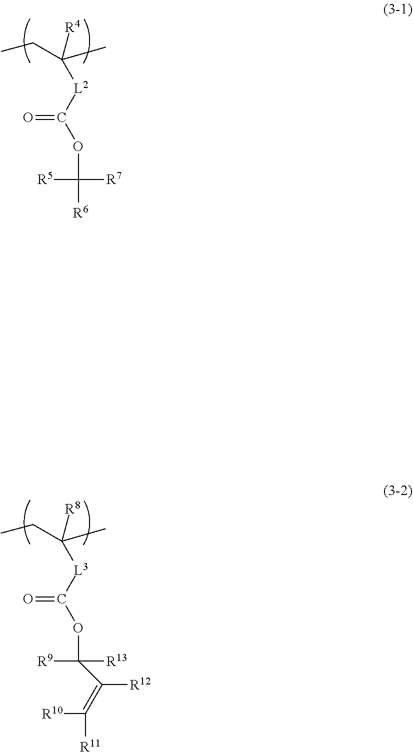
wherein,
in the formula (3-1), R⁴ represents a hydrogen atom, a halogen atom, or a monovalent organic group having 1 to 10 carbon atoms; L² represents a single bond or a divalent organic group having 1 to 20 carbon atoms; R⁵ represents a monovalent hydrocarbon group having 1 to 20 carbon atoms; and R⁶ and R⁷ each independently represent a monovalent hydrocarbon group having 1 to 20 carbon atoms, or R⁶ and R⁷ taken together represent an alicyclic structure having 3 to 20 ring atoms together with the carbon atom to which R⁶ and R⁷ bond; and
in the formula (3-2), R⁸ represents a hydrogen atom, a halogen atom, or a monovalent organic group having 1 to 10 carbon atoms; L³ represents a single bond or a divalent organic group having 1 to 20 carbon atoms; R⁹ and R¹⁰ each independently represent a hydrogen atom or a monovalent hydrocarbon group having 1 to 20 carbon atoms, or R⁹ and R¹⁰ taken together represent an unsaturated alicyclic structure having 4 to 20 ring atoms together with the carbon chain to which R⁹ and R¹⁰ bond; R¹¹ represents a hydrogen atom or a monovalent hydrocarbon group having 1 to 20 carbon atoms; and R¹² and R¹³ each independently represent a hydrogen atom or a monovalent hydrocarbon group having 1 to 20 carbon atoms, or R¹² and R¹³ taken together represent an alicyclic structure having 3 to 20 ring atoms together with the carbon chain to which R¹² and R¹³ bond.

5. The radiation-sensitive resin composition according to claim 1, further comprising a radiation-sensitive acid generator other than the compound represented by the formula (1).

6. The radiation-sensitive resin composition according to claim 5, wherein the radiation-sensitive acid generator is represented by formula (4): 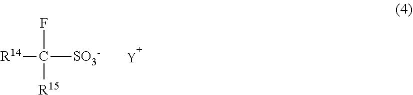
wherein, in the formula (4), R¹⁴ represents a monovalent organic group having 1 to 30 carbon atoms; R⁵ represents a hydrogen atom, a fluorine atom, or a monovalent organic group having 1 to 10 carbon atoms; and Y⁺ represents a monovalent radiation-sensitive onium cation.

7. The radiation-sensitive resin composition according to claim 1, wherein the polymer further comprises a third structural unit which comprises an aromatic carbon ring to which a single hydroxy group bonds.

8. The radiation-sensitive resin composition according to claim 7, wherein the third structural unit is represented by at least one selected from the group consisting of following formulae: 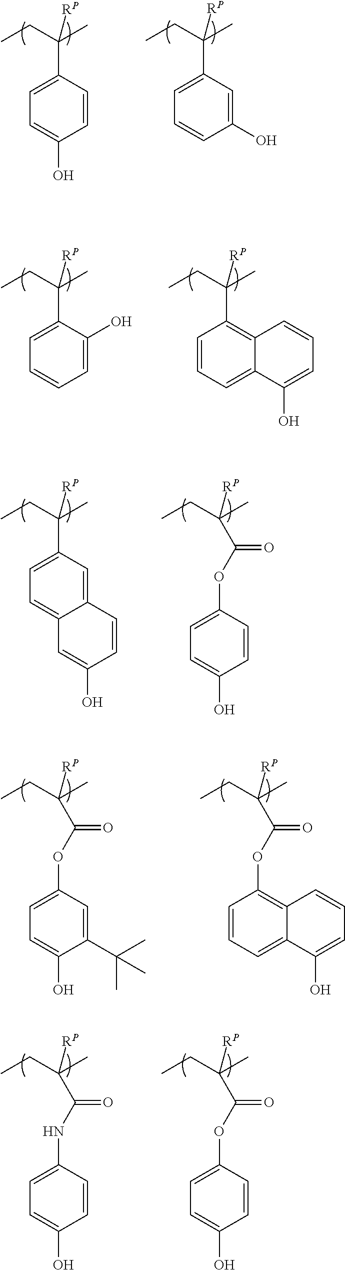 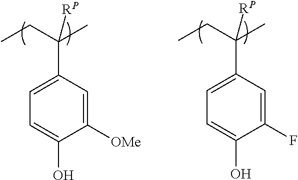
wherein R^{P} represents a hydrogen atom, a fluorine atom, a methyl group, or a trifluoromethyl group.

9. A method of forming a resist pattern, the method comprising:
applying a radiation-sensitive resin composition directly or indirectly on a substrate to form a resist film;
exposing the resist film; and
developing the resist film exposed,
wherein the radiation-sensitive resin composition comprises:
a polymer comprising a first structural unit comprising an aromatic carbon ring to which no less than two hydroxy groups bond, and a second structural unit comprising an acid-labile group which is dissociable by an action of an acid to give a carboxy group; and
a compound represented by formula (1):
R¹—COO⁻X⁺ (1)
wherein, in the formula (1), R¹ represents a monovalent organic group having 1 to 30 carbon atoms; and X⁺ represents a monovalent radiation-sensitive onium cation,
wherein a weight average molecular weight of the polymer is no greater than 10,000.

10. The method according to claim 9, wherein the first structural unit is represented by formula (2): 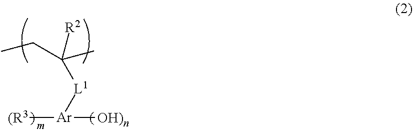
wherein, in the formula (2), R² represents a hydrogen atom, a halogen atom, or a monovalent organic group having 1 to 10 carbon atoms; L¹ represents a single bond, —O—, —COO—, or —CONH—; Ar represents a group obtained by removing (m+n+1) hydrogen atoms of an aromatic ring from an arene having 6 to 20 ring atoms; m is an integer of 0 to 9, wherein in a case in which m is 1, R³ represents a halogen atom or a monovalent organic group having 1 to 10 carbon atoms, and in a case in which m is no less than 2, a plurality of R³s are identical or different from each other and each R³ represents a halogen atom or a monovalent organic group having 1 to 10 carbon atoms, or two or more of the plurality of R³s taken together represent an alicyclic structure having 4 to 20 ring atoms together with the carbon chain to which the two or more of the plurality of R³s bond; and n is an integer of 2 to 11, wherein a sum of m and n is no greater than 11.

11. The method according to claim 10, wherein n in the formula (2) is 2.

12. The method according to claim 9, wherein the second structural unit is represented by formula (3-1) or (3-2): 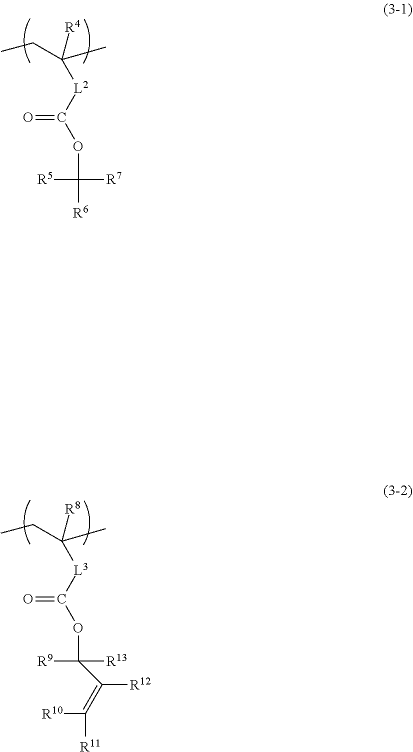
wherein,
in the formula (3-1), R⁴ represents a hydrogen atom, a halogen atom, or a monovalent organic group having 1 to 10 carbon atoms; L² represents a single bond or a divalent organic group having 1 to 20 carbon atoms; R⁵ represents a monovalent hydrocarbon group having 1 to 20 carbon atoms; and R⁶ and R⁷ each independently represent a monovalent hydrocarbon group having 1 to 20 carbon atoms, or R⁶ and R⁷ taken together represent an alicyclic structure having 3 to 20 ring atoms together with the carbon atom to which R⁶ and R⁷ bond; and
in the formula (3-2), R⁸ represents a hydrogen atom, a halogen atom, or a monovalent organic group having 1 to 10 carbon atoms; L³ represents a single bond or a divalent organic group having 1 to 20 carbon atoms; R⁹ and R¹⁰ each independently represent a hydrogen atom or a monovalent hydrocarbon group having 1 to 20 carbon atoms, or R⁹ and R¹⁰ taken together represent an unsaturated alicyclic structure having 4 to 20 ring atoms together with the carbon chain to which R⁹ and R¹⁰ bond; R¹¹ represents a hydrogen atom or a monovalent hydrocarbon group having 1 to 20 carbon atoms; and R¹² and R¹³ each independently represent a hydrogen atom or a monovalent hydrocarbon group having 1 to 20 carbon atoms, or R¹² and R¹³ taken together represent an alicyclic structure having 3 to 20 ring atoms together with the carbon chain to which R¹² and R¹³ bond.

13. The method according to claim 9, the radiation-sensitive resin composition further comprises radiation-sensitive acid generator other than the compound represented by the formula (1).

14. The method according to claim 13, wherein the radiation-sensitive acid generator is represented by formula (4): 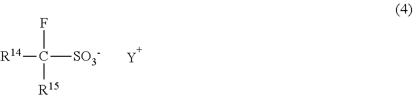
wherein, in the formula (4), R¹⁴ represents a monovalent organic group having 1 to 30 carbon atoms; R¹⁵ represents a hydrogen atom, a fluorine atom, or a monovalent organic group having 1 to 10 carbon atoms; and Y represents a monovalent radiation-sensitive onium cation.

15. The method according to claim 9, wherein the polymer further comprises a third structural unit which comprises an aromatic carbon ring to which a single hydroxy group bonds.

16. The method according to claim 15, wherein the third structural unit is represented by at least one selected from the group consisting of following formulae: 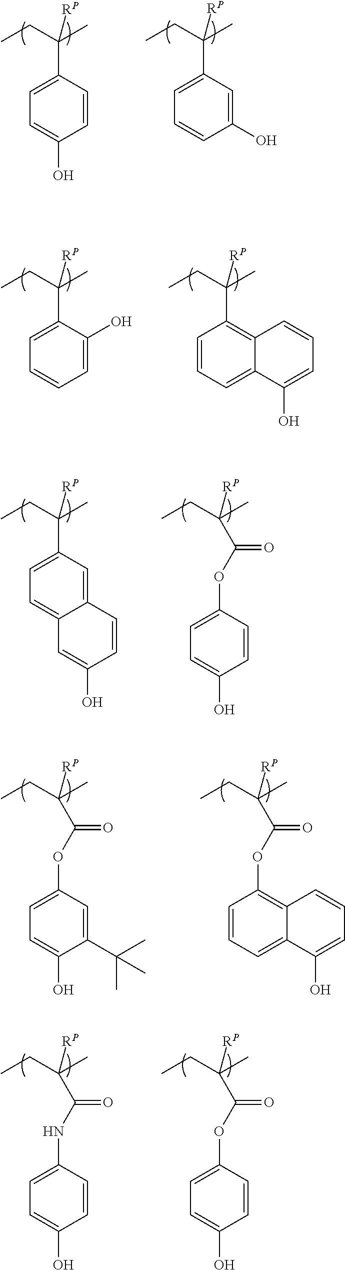 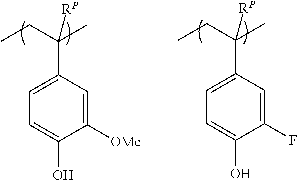
wherein R^{P} represents a hydrogen atom, a fluorine atom, a methyl group, or a trifluoromethyl group.
